(19) United States
(12) Patent Application Publication
(10) Pub. No.: US 2024/0321737 A1
(43) Pub. Date: Sep. 26, 2024

(54) ISOLATED BACKSIDE CONTACTS FOR SEMICONDUCTOR DEVICES

(71) Applicant: Intel Corporation, Santa Clara, CA (US)

(72) Inventors: Leonard P. Guler, Hillsboro, OR (US); Charles H. Wallace, Portland, OR (US); Shengsi Liu, Portland, OR (US); Saurabh Acharya, Hillsboro, OR (US)

(73) Assignee: Intel Corporation, Santa Clara, CA (US)

(21) Appl. No.: 18/125,440

(22) Filed: Mar. 23, 2023

(51) Int. Cl. H01L 23/528; H01L 27/092; H01L 29/06; H01L 29/423; H01L 29/66; H01L 29/778

(52) U.S. Cl. CPC H01L 23/5283; H01L 27/092; H01L 29/0665; H01L 29/42392; H01L 29/66545; H01L 29/778

(57) ABSTRACT

Techniques are provided herein to form semiconductor devices having one or more source or drain regions with backside contacts that are separated using dielectric walls. In an example, a first semiconductor device includes a first semiconductor region, such as one or more first nanoribbons, extending from a first source or drain region, and a second semiconductor device including a second semiconductor region, such as one or more second nanoribbons, extending from a second source or drain region adjacent to the first source or drain region. A first conductive contact abuts the underside of the first source or drain region and a second conductive contact abuts the underside of the second source or drain region. A dielectric wall extends between the first and second contacts, thus separating them from contacting each other. The dielectric wall also extends between the first source or drain region and the second source or drain region.

### FIELD OF THE DISCLOSURE

The present disclosure relates to integrated circuits, and more particularly, to the epitaxial region contact formation for transistor devices.

### BACKGROUND

As integrated circuits continue to scale downward in size, a number of challenges arise. For instance, reducing the size of memory and logic cells is becoming increasingly more difficult. Providing contacts to the various transistor structures presents a challenge as the devices continue to scale downward. Contacts can be made to the top side and/or bottom side of a given source or drain region, yet effectively isolating adjacent contacts can be difficult. Accordingly, there remain a number of non-trivial challenges with respect to semiconductor source or drain contact formation.

### BRIEF DESCRIPTION OF THE DRAWINGS

FIG. 1A is an isometric view of an integrated circuit structure that includes backside conductive contacts isolated by dielectric walls, in accordance with an embodiment of the present disclosure.

FIGS. 1B and 1C are cross-sectional views that illustrate a portion of a gate trench (1B) and a source/drain trench (1C) from FIG. 1A, in accordance with an embodiment of the present disclosure.

FIGS. 2A and 2B are cross-sectional views that illustrate one stage in an example process for forming an integrated circuit configured with backside conductive contacts isolated by dielectric walls, in accordance with an embodiment of the present disclosure.

FIGS. 3A and 3B are cross-sectional views that illustrate another stage in the example process for forming an integrated circuit configured with backside conductive contacts isolated by dielectric walls, in accordance with an embodiment of the present disclosure.

FIGS. 4A and 4B are cross-sectional views that illustrate another stage in the example process for forming an integrated circuit configured with backside conductive contacts isolated by dielectric walls, in accordance with an embodiment of the present disclosure.

FIGS. 5A and 5B are cross-sectional views that illustrate another stage in the example process for forming an integrated circuit configured with backside conductive contacts isolated by dielectric walls, in accordance with an embodiment of the present disclosure.

FIGS. 6A and 6B are cross-sectional views that illustrate another stage in the example process for forming an integrated circuit configured with backside conductive contacts isolated by dielectric walls, in accordance with an embodiment of the present disclosure.

FIGS. 7A and 7B are cross-sectional views that illustrate another stage in the example process for forming an integrated circuit configured with backside conductive contacts isolated by dielectric walls, in accordance with an embodiment of the present disclosure.

FIGS. 8A and 8B are cross-sectional views that illustrate another stage in the example process for forming an integrated circuit configured with backside conductive contacts isolated by dielectric walls, in accordance with an embodiment of the present disclosure.

FIGS. 9A and 9B are cross-sectional views that illustrate another stage in the example process for forming an integrated circuit configured with backside conductive contacts isolated by dielectric walls, in accordance with an embodiment of the present disclosure.

FIGS. 10A and 10B are cross-sectional views that illustrate another stage in the example process for forming an integrated circuit configured with backside conductive contacts isolated by dielectric walls, in accordance with an embodiment of the present disclosure.

FIGS. 11A and 11B are cross-sectional views that illustrate another stage in the example process for forming an integrated circuit configured with backside conductive contacts isolated by dielectric walls, in accordance with an embodiment of the present disclosure.

FIGS. 12A and 12B are cross-sectional views that illustrate another stage in the example process for forming an integrated circuit configured with backside conductive contacts isolated by dielectric walls, in accordance with an embodiment of the present disclosure.

FIGS. 13A and 13B are cross-sectional views that illustrate another stage in the example process for forming an integrated circuit configured with backside conductive contacts isolated by dielectric walls, in accordance with an embodiment of the present disclosure.

FIGS. 14A and 14B are cross-sectional views that illustrate another stage in the example process for forming an integrated circuit configured with backside conductive contacts isolated by dielectric walls, in accordance with an embodiment of the present disclosure.

FIG. 15 illustrates a cross-section view of a chip package containing one or more semiconductor dies, in accordance with some embodiments of the present disclosure.

FIG. 16 is a flowchart of a fabrication process for semiconductor device having backside conductive contacts isolated by dielectric walls, in accordance with an embodiment of the present disclosure.

FIG. 17 illustrates a computing system including one or more integrated circuits, as variously described herein, in accordance with an embodiment of the present disclosure.

Although the following Detailed Description will proceed with reference being made to illustrative embodiments, many alternatives, modifications, and variations thereof will be apparent in light of this disclosure. As will be further appreciated, the figures are not necessarily drawn to scale or intended to limit the present disclosure to the specific configurations shown. For instance, while some figures generally indicate perfectly straight lines, right angles, and smooth surfaces, an actual implementation of an integrated circuit structure may have less than perfect straight lines, right angles (e.g., some features may have tapered sidewalls and/or rounded corners), and some features may have surface topology or otherwise be non-smooth, given real world limitations of the processing equipment and techniques used.

### DETAILED DESCRIPTION

Techniques are provided herein to form semiconductor devices having one or more epitaxial source or drain regions with backside contacts that are separated from one another using dielectric walls. The backside contacts may be formed to facilitate connection with backside power rails and/or other backside signal layers. The techniques can be used in any number of integrated circuit applications and are particularly useful with respect to logic and memory cells, such as those cells that use finFETs or gate-all-around transistors. In an example, a first semiconductor device includes a first semiconductor region, such as one or more first nanoribbons, extending from a first source or drain region, and a second semiconductor device including a second semiconductor region, such as one or more second nanoribbons, extending from a second source or drain region adjacent to the first source or drain region. A first conductive contact abuts the underside of the first source or drain region and a second conductive contact abuts the underside of the second source or drain region. A dielectric wall extends between the first and second contacts, thus separating them from contacting each other. The dielectric wall also extends between the first source or drain region and the second source or drain region, and may further extend between gate electrodes around the first semiconductor region and the second semiconductor region. Numerous variations and embodiments will be apparent in light of this disclosure.

### General Overview

As previously noted above, there remain a number of non-trivial challenges with respect to epitaxial contact formation. Epitaxial contacts may be formed along the top surface of the source or drain regions for frontside contacts or formed on the bottom surface of the source or drain regions for backside contacts. However, such contacts are often formed very close together and are prone to shorting, which can render the circuit inoperable. Isolating structures such as dielectric layers or fills may be used to separate conductive elements, such as the contacts, from each other, however, such structures may be more complicated to form on the backside of the device.

Thus, and in accordance with an embodiment of the present disclosure, techniques are provided herein to form backside epitaxial contact structures that isolated from adjacent backside contacts by dielectric walls extending between the contacts and also between the adjacent epitaxial regions. Following the formation of semiconductor fins extending in a first direction that include semiconductor regions, source/drain trenches may be formed adjacent to gate trenches with both trenches running in a second direction orthogonal to the first direction, and at least a portion of the source or drain trenches is filled with a sacrificial material. The source or drain regions may be formed within the source/drain trenches and over the sacrificial material. Once gate structures have been formed within the gate trenches (e.g., after removing sacrificial gate material), one or more dielectric walls may be formed extending between adjacent fins and cutting through both the gate trenches and the source/drain trenches. Thus, according to some embodiments, the one or more dielectric walls extend in the first direction between devices and also extend in a third direction (e.g., Z-direction) through at least an entire thickness of the gate structures and through at least a portion of the sacrificial material within the source/drain trenches. Following the formation of any top-side interconnect structures (e.g., back-end-of-the-line structures), the substrate beneath the devices may be removed to expose an underside of the sacrificial material within the source/drain trenches. According to some embodiments, the dielectric walls between the devices is also exposed on the backside. The sacrificial material can then be removed and replaced with backside contacts, which will already be isolated from any adjacent contacts by the dielectric walls.

According to an embodiment, an integrated circuit includes a first semiconductor device having a first semiconductor region extending in a first direction from a first source or drain region, and a first gate electrode extending in a second direction over the first semiconductor region, and a second semiconductor device having a second semiconductor region extending in the first direction from a second source or drain region, and a second gate electrode extending in the second direction over the second semiconductor region. The second source or drain region is adjacent to the first source or drain region along the second direction. The integrated circuit further includes a first conductive contact on an underside of the first source or drain region, a second conductive contact on an underside of the second source or drain region, and a dielectric wall extending in the first direction between and contacting both the first gate electrode and the second gate electrode, extending in the first direction between the first source or drain region and the second source or drain region, and extending in the first direction between the first conductive contact and the second conductive contact. The first and second semiconductor regions may include one or more nanoribbons, nanowires, or nanosheets.

According to another embodiment, an integrated circuit includes a first semiconductor device having a first semiconductor region extending in a first direction from a first source or drain region, and a first gate structure extending in a second direction over the first semiconductor region. The first gate structure includes a first gate electrode and a first gate dielectric. The integrated circuit also includes a second semiconductor device having a second semiconductor region extending in the first direction from a second source or drain region, and a second gate structure extending in the second direction over the second semiconductor region. The second gate structure includes a second gate electrode and a second gate dielectric, and the second source or drain region is adjacent to the first source or drain region along the second direction. The integrated circuit also includes a dielectric layer beneath the first gate structure and the second gate structure, a first conductive contact extending through an entire thickness of the dielectric layer and contacting an underside of the first source or drain region, a second conductive contact extending through the entire thickness of the dielectric layer and contacting an underside of the second source or drain region, and a dielectric wall extending in the first direction between and contacting both the first gate electrode and the second gate electrode, extending in the first direction between the first conductive contact and the second conductive contact, and extending through an entire thickness of the dielectric layer.

According to another embodiment, a method of forming an integrated circuit includes forming a first fin comprising first semiconductor material and an adjacent second fin comprising second semiconductor material, the first and second fins extending above a substrate and extending in a first direction; forming a dielectric layer adjacent to a bottom portion of the first fin and the second fin; forming a sacrificial gate structures and spacer structures extending in a second direction over the first fin and second fin, such that portions of the first fin and second fin are not covered by the sacrificial gate structures and spacer structures; forming a recess between adjacent spacer structures by removing the portions of the first fin and the second fin, the bottom portion of the first fin and the second fin, and an entire thickness of the dielectric layer; forming a sacrificial material within the recess between the adjacent spacer structures; forming a first source or drain region at an end of the first fin within the recess and over the sacrificial material, and forming a second source or drain region at an end of the second fin within the recess and over the sacrificial material. forming a first conductive contact on a top surface of the first source or drain region within the recess and a second conductive contact on a top surface of the second source or drain region within the recess; replacing the sacrificial gate with a gate structure; forming a dielectric wall through an entire thickness of the gate structure and through an entire thickness of the sacrificial material, the dielectric wall extending in the first direction between the first source or drain region and the second source or drain region; removing the substrate to expose a backside of the sacrificial material; removing the sacrificial material; and forming a third conductive contact on a bottom surface of the first source or drain region and forming a fourth conductive contact on a bottom surface of the second source or drain region.

The techniques can be used with any type of non-planar transistors, including finFETs (sometimes called double-gate transistors, or tri-gate transistors), or nanowire, nanosheet, and nanoribbon transistors (sometimes called gate-all-around transistors), to name a few examples. The source and drain regions can be, for example, doped portions of a given fin or substrate, or epitaxial regions that are deposited during an etch-and-replace source/drain forming process. The dopant-type in the source and drain regions will depend on the polarity of the corresponding transistor. The source and drain regions may be any epitaxial diffusion region. The gate structure can be implemented with a gate-first process or a gate-last process (sometimes called a remove metal gate, or RMG, process). Any number of semiconductor materials can be used in forming the transistors, such as group IV materials (e.g., silicon, germanium, silicon germanium) or group III-V materials (e.g., gallium arsenide, indium gallium arsenide).

Use of the techniques and structures provided herein may be detectable using tools such as electron microscopy including scanning/transmission electron microscopy (SEM/TEM), scanning transmission electron microscopy (STEM), nano-beam electron diffraction (NBD or NBED), and reflection electron microscopy (REM); composition mapping; x-ray crystallography or diffraction (XRD); energy-dispersive x-ray spectroscopy (EDX); secondary ion mass spectrometry (SIMS); time-of-flight SIMS (ToF-SIMS); atom probe imaging or tomography; local electrode atom probe (LEAP) techniques; 3D tomography; or high resolution physical or chemical analysis, to name a few suitable example analytical tools. For instance, in some example embodiments, such tools may indicate the presence of backside epitaxial contacts separated by dielectric walls that further extend between the epitaxial regions and also between the gate structures. Numerous configurations and variations will be apparent in light of this disclosure.

It should be readily understood that the meaning of “above” and “over” in the present disclosure should be interpreted in the broadest manner such that “above” and “over” not only mean “directly on” something but also include the meaning of over something with an intermediate feature or a layer therebetween. Further, spatially relative terms, such as “beneath,” “below,” “lower,” “above,” “upper,” “top,” “bottom,” and the like, may be used herein for ease of description to describe one element or feature's relationship to another element (s) or feature (s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

As used herein, the term “layer” refers to a material portion including a region with a thickness. A monolayer is a layer that consists of a single layer of atoms of a given material. A layer can extend over the entirety of an underlying or overlying structure, or may have an extent less than the extent of an underlying or overlying structure. Further, a layer can be a region of a homogeneous or inhomogeneous continuous structure, with the layer having a thickness less than the thickness of the continuous structure. For example, a layer can be located between any pair of horizontal planes between, or at, a top surface and a bottom surface of the continuous structure. A layer can extend horizontally, vertically, and/or along a tapered surface. A layer can be conformal to a given surface (whether flat or curvilinear) with a relatively uniform thickness across the entire layer.

Materials that are “compositionally different” or “compositionally distinct” as used herein refers to two materials that have different chemical compositions. This compositional difference may be, for instance, by virtue of an element that is in one material but not the other (e.g., SiGe is compositionally different than silicon), or by way of one material having all the same elements as a second material but at least one of those elements is intentionally provided at a different concentration in one material relative to the other material (e.g., SiGe having 70 atomic percent germanium is compositionally different than from SiGe having 25 atomic percent germanium). In addition to such chemical composition diversity, the materials may also have distinct dopants (e.g., gallium and magnesium) or the same dopants but at differing concentrations. In still other embodiments, compositionally distinct materials may further refer to two materials that have different crystallographic orientations. For instance, (110) silicon is compositionally distinct or different from (100) silicon. Creating a stack of different orientations could be accomplished, for instance, with blanket wafer layer transfer. If two materials are elementally different, then one of the materials has an element that is not in the other material.

### Architecture

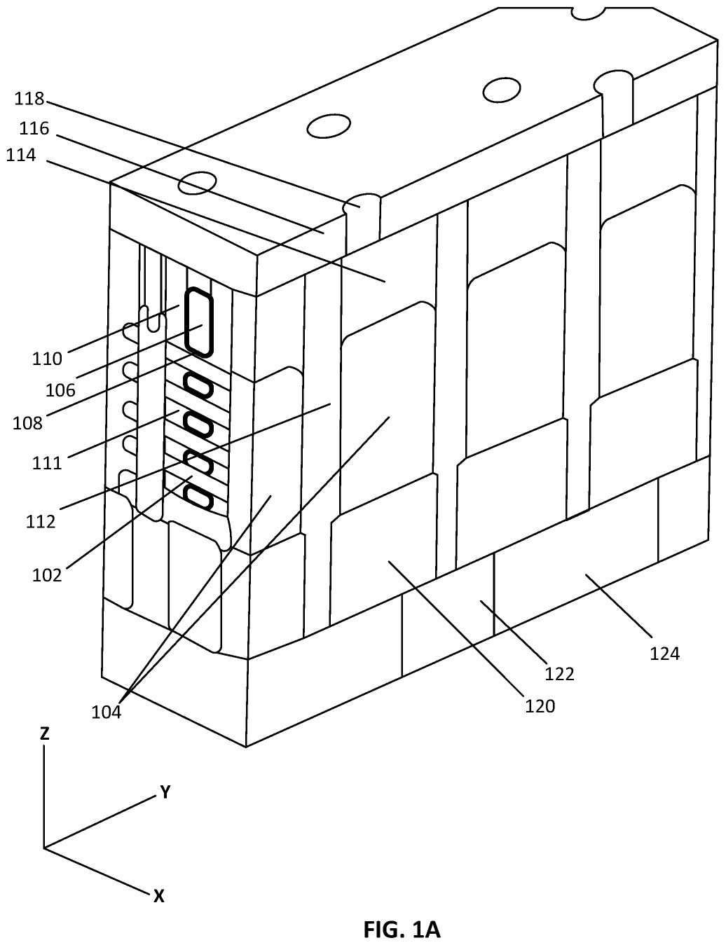

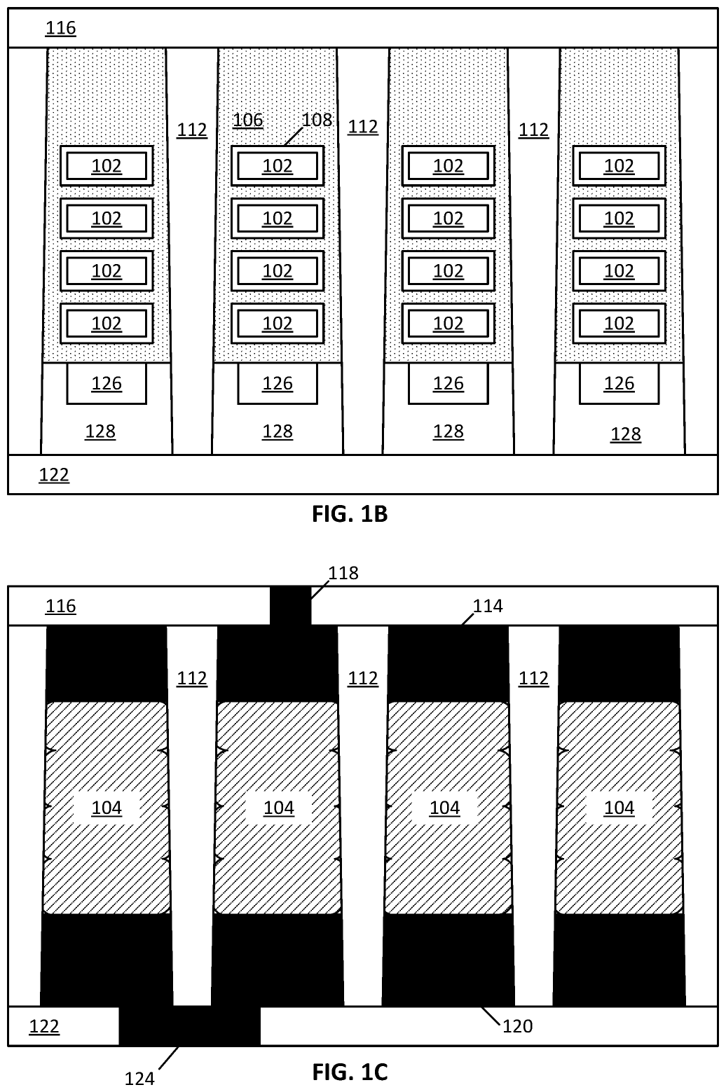

FIG. 1 is an isometric view of a portion of an integrated circuit that includes various parallel semiconductor devices, in accordance with an embodiment of the present disclosure. Each of the semiconductor devices may be non-planar metal oxide semiconductor (MOS) transistors, such as tri-gate or gate-all-around transistors, although other transistor topologies and types could also benefit from the techniques provided herein. The examples herein illustrate semiconductor devices with a GAA structure (e.g., having nanoribbons, nanowires, or nanosheets that extend between source or drain regions).

Each semiconductor device includes one or more nanoribbons 102 extending between epitaxial source or drain regions 104 in a first direction along the X-axis. A gate structure that includes a gate electrode 106 and a gate dielectric 108 extend over the one or more nanoribbons 102 in a second direction (e.g. along the Y-axis) to form the transistor gate. A given gate structure may extend over the semiconductor regions of more than one semiconductor device. It should be noted that the one or more nanoribbons 102 of each device may also be fins in trigate transistor designs.

The semiconductor material used in each of the semiconductor devices may be formed from a semiconductor substrate. As noted above, the one or more semiconductor regions of the devices may include fins that can be, for example, native to the substrate (formed from the substrate itself), such as silicon fins etched from a bulk silicon substrate. Alternatively, the fins can be formed of material deposited onto an underlying substrate. In one such example case, a blanket layer of silicon germanium (SiGe) can be deposited onto a silicon substrate, and then patterned and etched to form a plurality of SiGe fins extending from that substrate. In still other embodiments, the fins include alternating layers of material (e.g., alternating layers of silicon and SiGe) that facilitates forming of nanowires and nanoribbons (such as the illustrated nanoribbons 102) during a gate forming process where one type of the alternating layers are selectively etched away so as to liberate the other type of alternating layers within the channel region, so that a gate-all-around process can then be carried out. Again, the alternating layers can be blanket deposited and then etched into fins or deposited into fin-shaped trenches. The substrate may be later removed from the backside to form backside interconnects to source or drain regions 104 and/or gate electrode 106.

Source or drain regions 104 may be formed at the ends of the one or more nanoribbons 102 of each device, and thus may be aligned along the second direction from one another. According to some embodiments, source or drain regions 104 are epitaxial regions that are provided on the semiconductor regions in an etch-and-replace process. In other embodiments source or drain regions 104 could be, for example, implantation-doped native portions of the fins or substrate. Any semiconductor materials suitable for source or drain regions can be used (e.g., group IV and group III-V semiconductor materials). Source or drain regions 104 may include multiple layers such as liners and capping layers to improve contact resistance. In any such cases, the composition and doping of source or drain regions 104 may be the same or different, depending on the polarity of the transistors. Any number of source or drain configurations and materials can be used.

As noted above, a gate structure extends in the second direction over the one or more nanoribbons 102 of various devices and includes both gate electrode 106 and gate dielectric 108. Gate electrode 106 may include any sufficiently conductive material such as a metal, metal alloy, or doped polysilicon. In some embodiments, gate electrode 106 includes one or more workfunction metals around the one or more semiconductor regions. In some embodiments, p-channel devices include a workfunction metal having titanium around its one or more semiconductor regions and n-channel devices include a workfunction metal having tungsten around its one or more semiconductor regions. Gate electrode 106 may also include a fill metal or other conductive material around the workfunction metals to provide the whole gate electrode structure. Gate dielectric 108 represents any number of dielectric layers that exist between the one or more nanoribbons 102 and gate electrode 106.

According to some embodiments, spacer structures 110 are present on the sidewalls of the gate structure and define a gate trench through which the gate structure is formed. Spacer structures 110 may include any suitable dielectric material such as silicon nitride or silicon oxynitride. In some embodiments, gate dielectric 108 also forms along sidewalls of spacer structures 110. Inner spacers 111 are present between adjacent nanoribbons 102 and may be the same dielectric material as spacer structures 110 (but formed at a later time as will be discussed in more detail herein).

According to some embodiments, one or more dielectric walls 112 extend across the gate structure in the first direction (e.g., parallel to the length of nanoribbons 102) and also extend across the source/drain trench to be between adjacent source or drain regions 104 within the source/drain trench. Dielectric walls 112 may continue to extend in the first direction across any number of other gate trenches and source/drain trenches to be between other adjacent source or drain regions in other source/drain trenches. According to some embodiments, one or more dielectric walls 112 includes any suitable dielectric material, such as silicon nitride, silicon oxide, or silicon oxynitride. One or more dielectric walls 112 may extend both above and below the height of source or drain regions 104. One or more dielectric walls 112 may include the same dielectric material as spacer structures 110.

According to some embodiments, topside contacts 114 may be provided on an upper surface of any of source or drain regions 104. Topside contacts 114 may be flanked on two sides by corresponding dielectric walls 112, such that dielectric walls 112 extend along an entire thickness of topside contacts 114. Topside contacts 114 may include any suitable conductive material, such as tungsten, ruthenium, molybdenum, or cobalt, to name a few examples. Topside contacts 114 may include a highly conductive silicide or germanide layer directly on the upper surface of source or drain regions 104. Topside contacts 114 may include one or more barrier layers that include tantalum or titanium.

According to some embodiments, the integrated circuit includes back-end-of-the-line (BEOL) structures, such as a topside interconnect layer that includes a dielectric layer 116 and one or more conductive vias 118 extending through at least a portion of dielectric layer 116 to contact one or more corresponding topside contacts 114. Dielectric layer 116 may include any suitable dielectric material, such as silicon dioxide, silicon nitride, or silicon oxynitride. Conductive via 118 may include any suitable conductive materials, such as tungsten, ruthenium, molybdenum, or cobalt. In some examples, conductive via 118 includes the same conductive material as the underlying topside contact 114. Conductive via 118 may include one or more barrier layers that include tantalum or titanium.

According to some embodiments the integrated circuit includes backside contacts 120 that contact the underside of any of source or drain regions 104. Backside contacts 120 may be flanked on two sides by corresponding dielectric walls 112, such that dielectric walls 112 extend along an entire thickness of backside contacts 120. Accordingly, dielectric walls 112 may extend in a third direction (e.g., along the Z-axis) along an entire thickness of each of topside contacts 114, source or drain regions 104, and backside contacts 120. Due to some lateral etching that may occur to dielectric walls 112 during backside processing, portions of backside contacts 120 may extend slightly into dielectric walls 112 at the base of source or drain regions 104, as will be discussed in more detail herein. Backside contacts 120 may include any of the same materials discussed above for topside contacts 114, and may be the same conductive material as topside contacts 114.

According to some embodiments, the integrated circuit includes backside interconnect structures, such as a backside interconnect layer that includes a dielectric layer 122 and one or more conductive traces 124 extending through at least a portion of dielectric layer 122 to contact one or more corresponding backside contacts 120. Dielectric layer 122 may include any suitable dielectric material, such as silicon dioxide, silicon nitride, or silicon oxynitride. Conductive traces 124 may include any suitable conductive materials, such as tungsten, ruthenium, molybdenum, or cobalt. In some examples, conductive traces 124 includes the same conductive material as backside contacts 120. Conductive traces 124 may include one or more barrier layers that include tantalum or titanium.

FIGS. 1B and 1C illustrate cross-section views taken across the gate trench (FIG. 1B) and source/drain trench (FIG. 1C) along the YZ plane of FIG. 1A, according to some embodiments. As can be seen along the gate trench in the cross-section of FIG. 1B, portions of subfins 126 are below corresponding nanoribbons 102, along with a dielectric fill 128 adjacent and/or partially surrounding subfins 126. Dielectric fill 128 may include any suitable dielectric material such as silicon oxide. Dielectric fill 128 may provide shallow trench isolation (STI) between adjacent semiconductor devices. According to some embodiments, subfins 126 are portions of the semiconductor fins that remain after formation of the various transistors and may be formed from the semiconductor substrate. Accordingly, subfins 126 may include the same semiconductor material as the one or more nanoribbons 102 of the semiconductor devices.

### Fabrication Methodology

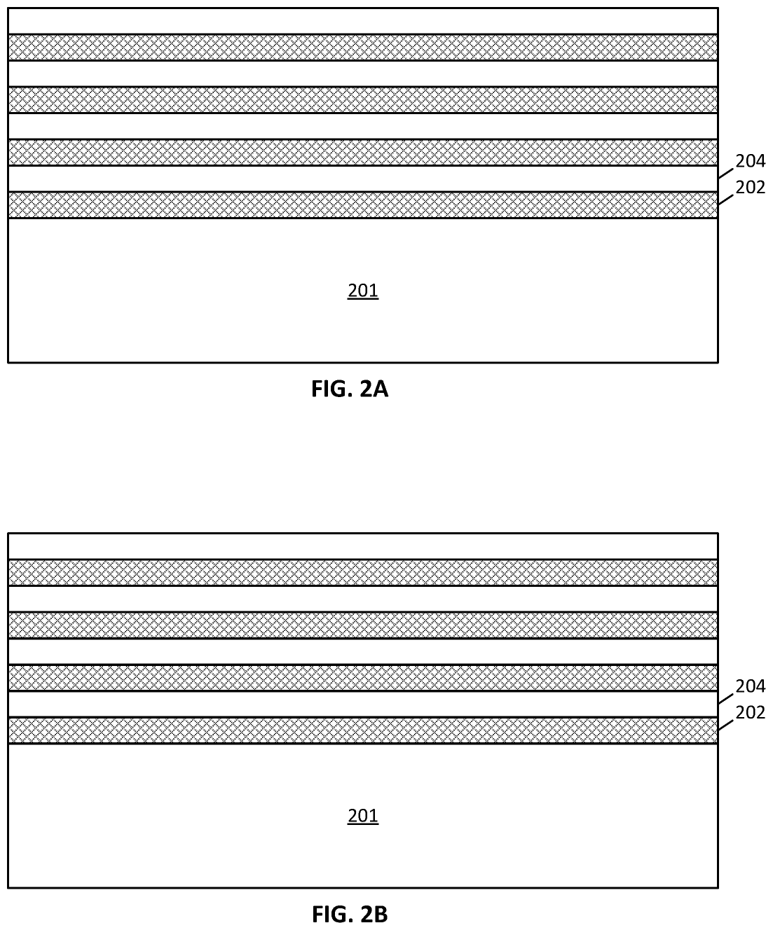

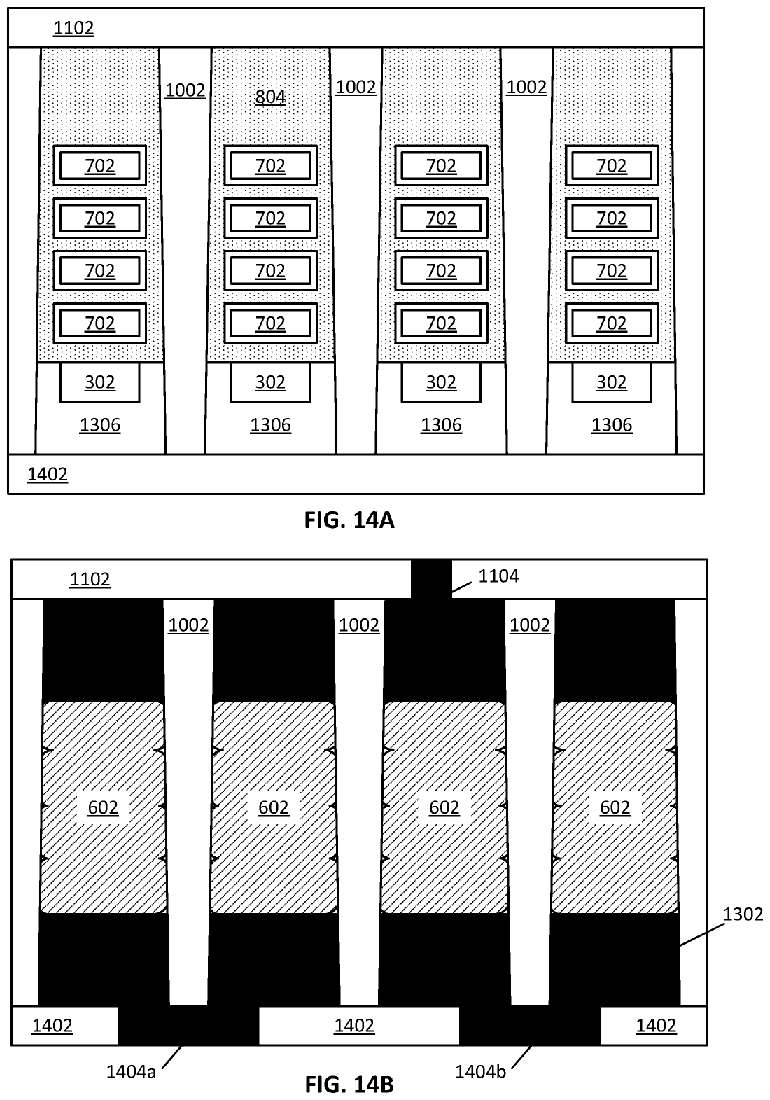

FIGS. 2A-14A and 2B-14B are cross-sectional views that collectively illustrate an example process for forming an integrated circuit configured with backside conductive contacts isolated by dielectric walls, in accordance with an embodiment of the present disclosure. FIGS. 2A-14A represent cross-sectional views taken across a gate trench of the integrated circuit, while FIGS. 2B-14B represent cross-sectional views taken across the source/drain trench adjacent to the gate trench along the same direction. Each figure shows an example structure that results from the process flow up to that point in time, so the depicted structure evolves as the process flow continues, culminating in the structure shown in FIGS. 14A and 14B, which is similar to the structure shown in FIGS. 1B and 1C, respectively. Such a structure may be part of an overall integrated circuit (e.g., such as a processor or memory chip) that includes, for example, digital logic cells and/or memory cells and analog mixed signal circuitry. Thus, the illustrated integrated circuit structure may be part of a larger integrated circuit that includes other integrated circuitry not depicted. Example materials and process parameters are given, but the present disclosure is not intended to be limited to any specific such materials or parameters, as will be appreciated. Figures sharing the same number (e.g., FIGS. 2A and 2B) illustrate different views of the structure at the same point in time during the process flow.

FIGS. 2A and 2B illustrate parallel cross-sectional views taken through a stack of alternating semiconductor layers on a semiconductor substrate 201. FIG. 2A is taken across a portion of the stack that will eventually become a gate trench while FIG. 2B is taken across a portion of the stack that will eventually become a source/drain trench adjacent and parallel to the gate trench. Alternating material layers may be deposited over substrate 201 including sacrificial layers 202 alternating with semiconductor layers 204. The alternating layers are used to form GAA transistor structures. Any number of alternating semiconductor layers 204 and sacrificial layers 202 may be deposited over substrate 201.

Substrate 201 can be, for example, a bulk substrate including group IV semiconductor material (such as silicon, germanium, or silicon germanium), group III-V semiconductor material (such as gallium arsenide, indium gallium arsenide, or indium phosphide), and/or any other suitable material upon which transistors can be formed. Alternatively, substrate 201 can be a semiconductor-on-insulator substrate having a desired semiconductor layer over a buried insulator layer (e.g., silicon over silicon dioxide). Alternatively, substrate 201 can be a multilayer substrate or superlattice suitable for forming nanowires or nanoribbons (e.g., alternating layers of silicon and SiGe, or alternating layers indium gallium arsenide and indium phosphide). Any number of substrates can be used.

According to some embodiments, sacrificial layers 202 have a different material composition than semiconductor layers 204. In some embodiments, sacrificial layers 202 are silicon germanium (SiGe) while semiconductor layers 204 include a semiconductor material suitable for use as a nanoribbon such as silicon (Si), SiGe, germanium, or III-V materials like indium phosphide (InP) or gallium arsenide (GaAs). In examples where SiGe is used in each of sacrificial layers 202 and in semiconductor layers 204, the germanium concentration is different between sacrificial layers 202 and semiconductor layers 204. For example, sacrificial layers 202 may include a higher germanium content compared to semiconductor layers 204. In some examples, semiconductor layers 204 may be doped with either n-type dopants (to produce a p-channel transistor) or p-type dopants (to produce an n-channel transistor).

While dimensions can vary from one example embodiment to the next, the thickness of each sacrificial layer 202 may be between about 5 nm and about 20 nm. In some embodiments, the thickness of each sacrificial layer 202 is substantially the same (e.g., within 1-2 nm). The thickness of each of semiconductor layers 204 may be about the same as the thickness of each sacrificial layer 202 (e.g., about 5-20 nm). Each of sacrificial layers 202 and semiconductor layers 204 may be deposited using any known or proprietary material deposition technique, such as chemical vapor deposition (CVD), plasma-enhanced chemical vapor deposition (PECVD), physical vapor deposition (PVD), or atomic layer deposition (ALD).

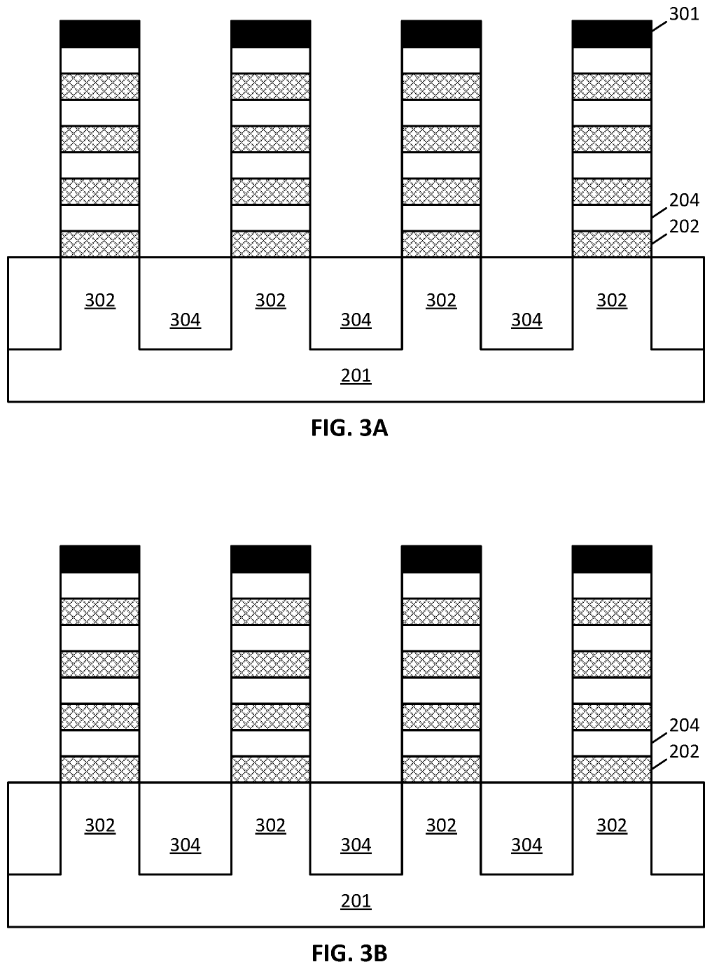

FIGS. 3A and 3B depict the cross-section views of the structure shown in FIGS. 2A and 2B, respectively, following the formation of a cap layer 301 and the subsequent formation of fins beneath cap layer 301, according to an embodiment. Cap layer 301 may be any suitable hard mask material such as a carbon hard mask (CHM) or silicon nitride. Cap layer 301 is patterned into rows to form corresponding rows of fins from the alternating layer stack of sacrificial layers 202 and semiconductor layers 204. The rows of fins extend lengthwise in a first direction (e.g., into and out of the page of each cross-section view).

According to some embodiments, an anisotropic etching process through the layer stack continues into at least a portion of substrate 201, where the unetched portions of substrate 201 beneath the fins form subfin regions 302. The etched portions of substrate 201 may be filled with a dielectric fill 304 that acts as shallow trench isolation (STI) between adjacent fins. Dielectric fill 304 may be any suitable dielectric material such as silicon oxide, and may be recessed to a desired depth as shown (in this example case, down to around the upper surface of subfin regions 302), so as to define the active portion of the fins that will be covered by a gate structure.

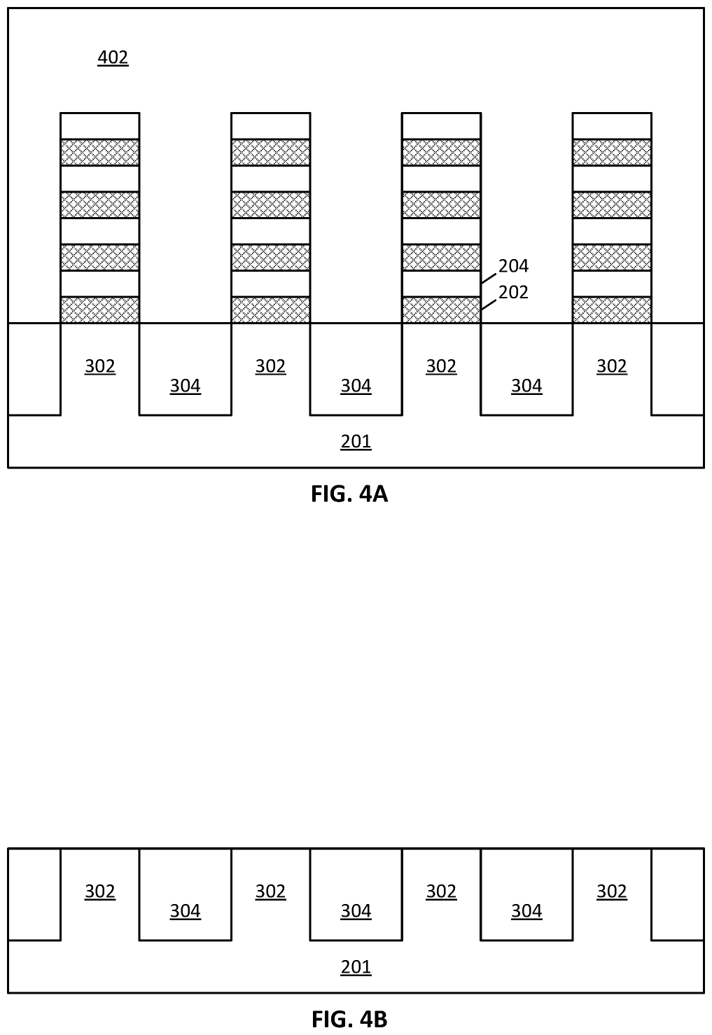

FIGS. 4A and 4B depict the cross-section views of the structure shown in FIGS. 3A and 3B, respectively, following the formation of a sacrificial gate 402 extending across the fins in a second direction different from the first direction, according to some embodiments. Sacrificial gate 402 may extend across the fins in a second direction that is orthogonal to the first direction. According to some embodiments, the sacrificial gate material is formed in parallel strips across the integrated circuit and removed in all areas not protected by a gate masking layer. Sacrificial gate 402 may be any suitable material that can be selectively removed without damaging the semiconductor material of the fins. In some examples, sacrificial gate 402 includes polysilicon.

As seen in the cross-section views, sacrificial gate 402 extends across the fins along the gate trench cross-section of FIG. 4A but is not present along the source/drain trench cross-section of FIG. 4B. Accordingly, sacrificial gate 402 (along with any gate spacers formed on the sidewalls of sacrificial gate 402) protect the underlying portions of the fins while the exposed portions of the fins are etched away as seen in FIG. 4B. According to some embodiments, both semiconductor layers 204 and sacrificial layers 202 are etched at substantially the same rate using an anisotropic RIE process. As observed in FIG. 4B, the fins are completely removed above subfin regions 302. In some embodiments, the RIE process may also etch into subfin regions 302 thus recessing subfin regions 302 beneath a top surface of dielectric fill 304.

According to some embodiments, the exposed portions of sacrificial layers 202 along the edges of the gate spacers may be recessed and the recessed can be filled with internal spacer material. The internal spacer material may be conformally deposited over the exposed ends of the fins and then etched back to fill the recesses with internal spacers and expose the ends of semiconductor layers 204.

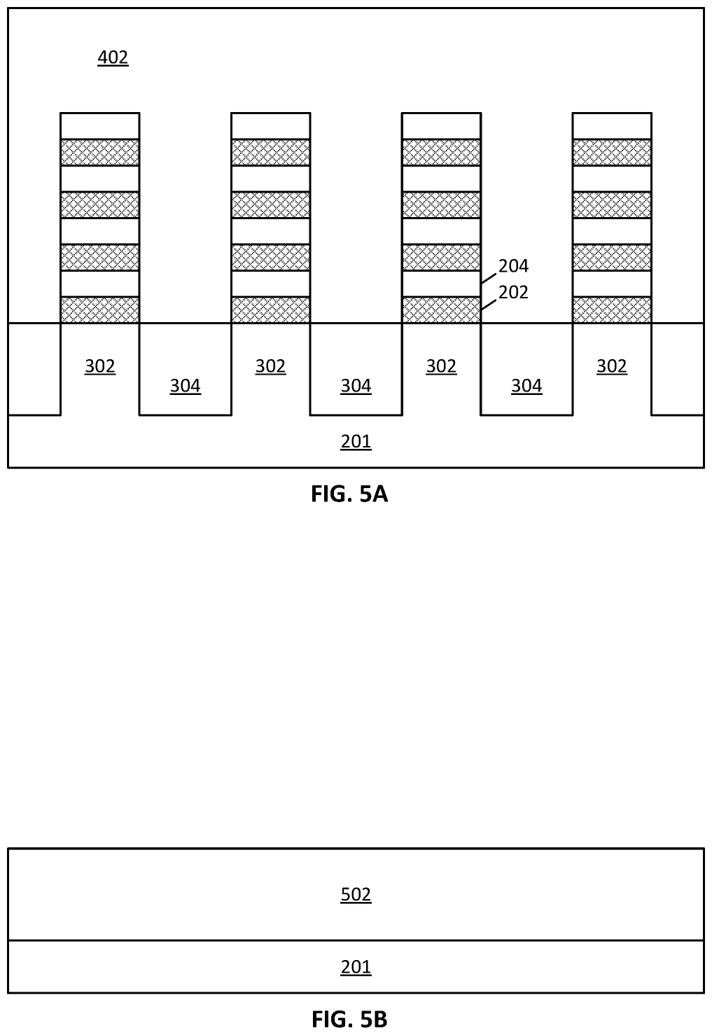

FIGS. 5A and 5B depict the cross-section views of the structure shown in FIGS. 4A and 4B, respectively, following the removal of at least subfin regions 302 within the source/drain trench and formation of sacrificial material 502 within the source/drain trench, according to some embodiments. According to some embodiments, a reactive ion etching (RIE) process may be used to remove the exposed subfin regions 302 and the adjacent dielectric fill 304 within the source/drain trench. Portions of substrate 201 may also be removed during this process. Afterwards, at least a portion of the source/drain trench is filled with sacrificial material 502 on top of substrate 201, according to some embodiments. Sacrificial material 502 may be any suitable material that can be easily removed at a later time without damaging any surrounding structures. In some examples, sacrificial material 502 includes titanium nitride or tungsten. After deposition of sacrificial material 502, it may be recessed to a final thickness such that a top surface of sacrificial material 502 is substantially coplanar (e.g., within 2 nm) of a top surface of dielectric fill 304 and/or subfin regions 302.

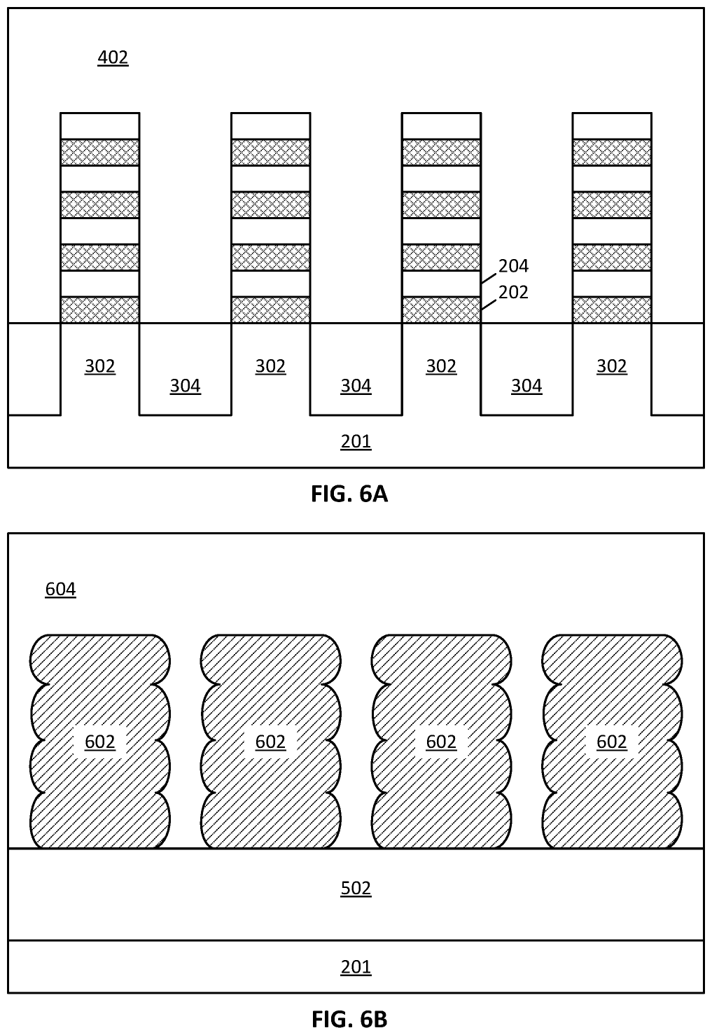

FIGS. 6A and 6B depict the cross-section views of the structure shown in FIGS. 5A and 5B, respectively, following the formation of source or drain regions 602 at the ends of each of the fins (extending into and out of the page in FIG. 6A), according to some embodiments. Source or drain regions 602 may be epitaxially grown from the exposed ends of semiconductor layers 204, such that the material grows together or otherwise merges towards the middle of the trenches between fins, according to some embodiments. Note that epitaxial growth on one semiconductor layer 204 can fully or partially merge with epitaxial growth on one or more other semiconductor layers 204 in the same vertical stack. The degree of any such merging can vary from one embodiment to the next. In the example of a PMOS device, a given source or drain region 602 may be a semiconductor material (e.g., group IV or group III-V semiconductor materials) having a higher dopant concentration of p-type dopants compared to n-type dopants. In the example of an NMOS device, a given source or drain region 602 may be a semiconductor material (e.g., group IV or group III-V semiconductor materials) having a higher dopant concentration of n-type dopants compared to p-type dopants. According to some embodiments, the various source or drain regions 602 grown from different semiconductor devices may be aligned along the second direction as shown in FIG. 6B. Source or drain regions 602 may be formed directly on sacrificial material 502.

According to some embodiments, a dielectric fill 604 is provided within the source/drain trench and around source or drain regions 602. Dielectric fill 604 may extend between adjacent ones of the source or drain regions 602 along the second direction and also may extend up and over each of the source or drain regions 602, according to some embodiments. Accordingly, each source or drain region 602 may be isolated from any adjacent source or drain regions 602 by dielectric fill 604. Dielectric fill 604 may be any suitable dielectric material, although in some embodiments, dielectric fill 604 includes the same dielectric material as dielectric fill 304. In one example, both dielectric fill 604 and dielectric fill 304 include silicon dioxide. According to some embodiments, a top surface of dielectric fill 604 may be polished using, for example, chemical mechanical polishing (CMP). The top surface of dielectric fill 604 may be polished until it is substantially coplanar with a top surface of sacrificial gate 402.

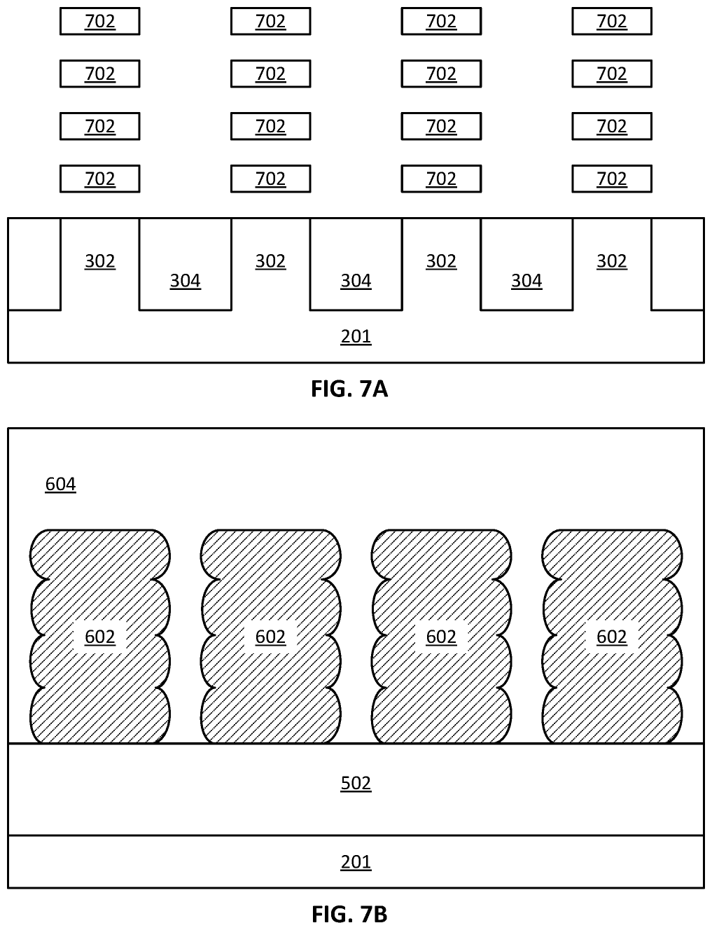

FIGS. 7A and 7B depict the cross-section views of the structure shown in FIGS. 6A and 6B, respectively, following the formation of nanoribbons 702 from semiconductor layers 204, according to some embodiments. Depending on the dimensions of the structures, nanoribbons 702 may also be considered nanowires or nanosheets. Sacrificial gate 402 may be removed using any wet or dry isotropic process thus exposing the alternating layer stack of the fins within the trenches left behind after the removal of sacrificial gate 402. Once sacrificial gate 402 is removed, sacrificial layers 202 may also be removed using a selective isotropic etching process that removes the material of sacrificial layers 202 but does not remove (or removes very little of) semiconductor layers 204 or any other exposed layers (e.g., inner gate spacers). Sacrificial gate 402 and sacrificial layers 202 may be removed together using the same isotropic etching process. At this point, the suspended (sometimes called released) semiconductor layers 204 form nanoribbons 702 that extend in the first direction (into and out of the page) between corresponding source or drain regions 602 and other source or drain regions on the opposite ends of nanoribbons 702.

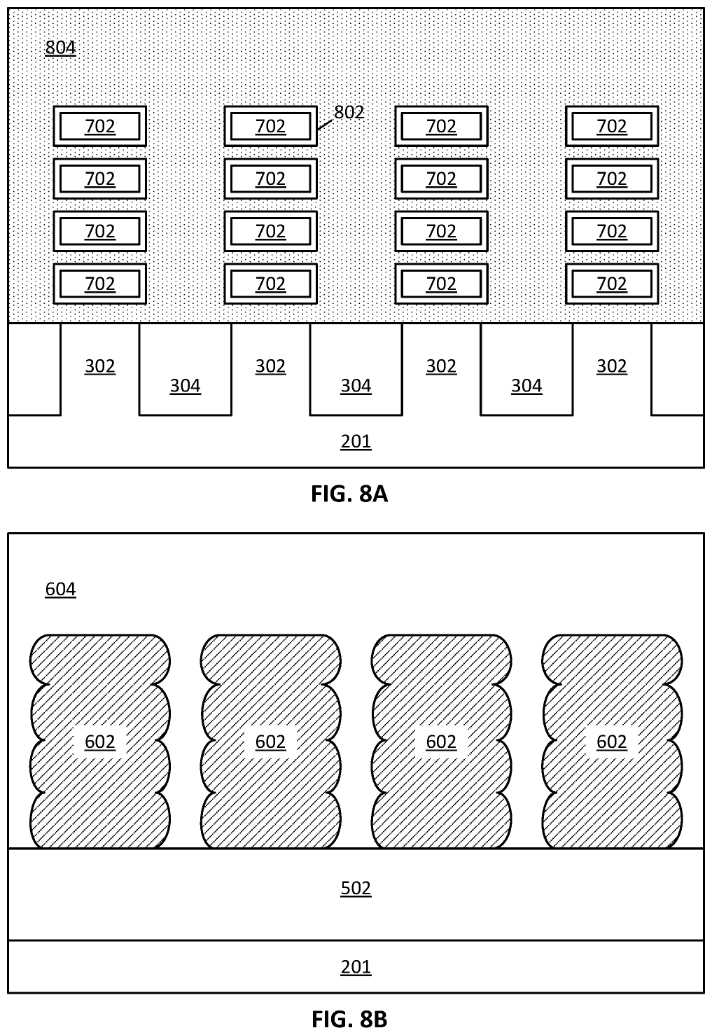

FIGS. 8A and 8B depict the cross-section views of the structure shown in FIGS. 7A and 7B, respectively, following the formation of a gate structure around nanoribbons 702 within the gate trench, according to some embodiments. As noted above, the gate structure includes a gate dielectric 802 and a gate electrode 804. Gate dielectric 802 may be conformally deposited around nanoribbons 702 using any suitable deposition process, such as atomic layer deposition (ALD). Gate dielectric 802 may include any suitable dielectric (such as silicon dioxide, and/or a high-k dielectric material). Examples of high-k dielectric materials include, for instance, hafnium oxide, hafnium silicon oxide, lanthanum oxide, lanthanum aluminum oxide, zirconium oxide, zirconium silicon oxide, tantalum oxide, titanium oxide, barium strontium titanium oxide, barium titanium oxide, strontium titanium oxide, yttrium oxide, aluminum oxide, lead scandium tantalum oxide, and lead zinc niobate, to provide some examples. According to some embodiments, gate dielectric 802 is hafnium oxide with a thickness between about 1 nm and about 5 nm. In some embodiments, gate dielectric 802 may include one or more silicates (e.g., titanium silicate, tungsten silicate, niobium silicate, and silicates of other transition metals). Gate dielectric 802 may be a multilayer structure, in some examples. For instance, gate dielectric 802 may include a first layer on nanoribbons 702, and a second layer on the first layer. The first layer can be, for instance, an oxide of the semiconductor layers (e.g., silicon dioxide) and the second layer can be a high-k dielectric material (e.g., hafnium oxide). In some embodiments, an annealing process may be carried out on gate dielectric 802 to improve its quality when a high-k dielectric material is used. In some embodiments, the high-k material can be nitridized to improve its aging resistance.

Gate electrode 804 may be deposited over gate dielectric 802 and can be any standard or proprietary conductive structure. In some embodiments, gate electrode 804 includes doped polysilicon, a metal, or a metal alloy. Example suitable metals or metal alloys include aluminum, tungsten, cobalt, molybdenum, ruthenium, titanium, tantalum, copper, and carbides and nitrides thereof. Gate electrode 804 may include, for instance, one or more workfunction layers, resistance-reducing layers, and/or barrier layers. The workfunction layers can include, for example, p-type workfunction materials (e.g., titanium nitride) for PMOS gates, or n-type workfunction materials (e.g., titanium aluminum carbide) for NMOS gates.

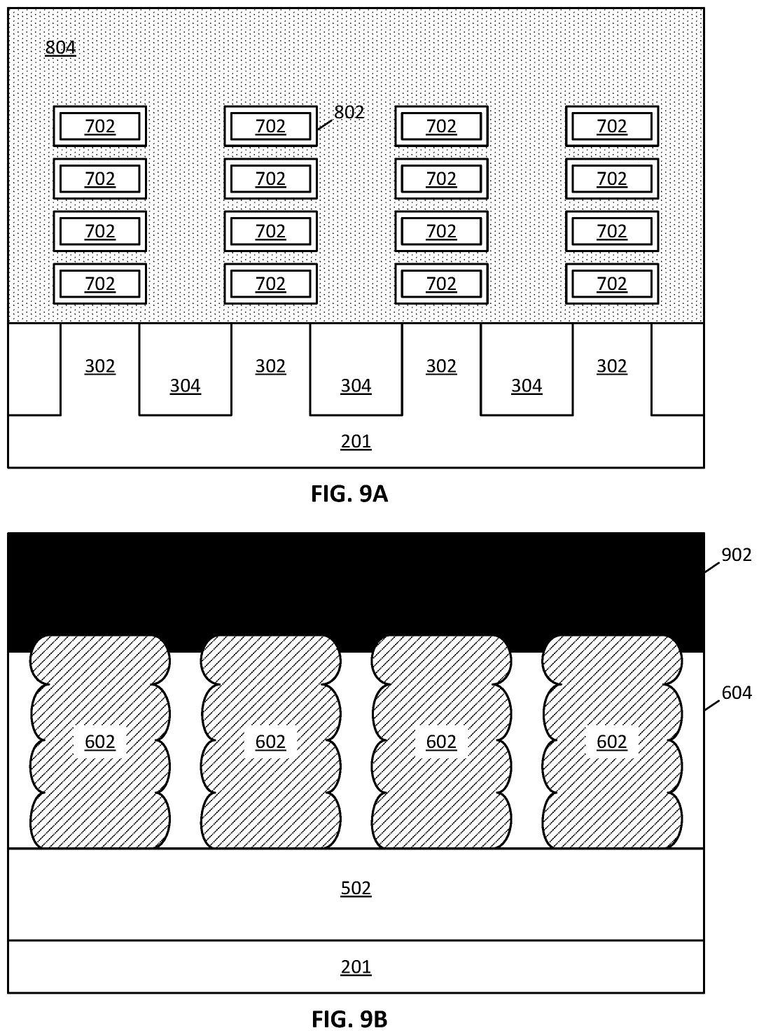

FIGS. 9A and 9B depict the cross-section views of the structure shown in FIGS. 8A and 8B, respectively, following the formation of a conductive contact 902 within source/drain trench and on an upper surface of source or drain regions 602, according to some embodiments. A top portion of dielectric fill 604 may first be recessed until at least a top surface of source or drain regions 602 is exposed. Then, conductive contact 902 may be formed within the recessed volume above source or drain regions 602. Conductive contact 902 may include any suitably conductive material such as tungsten, ruthenium (Ru), cobalt (Co), titanium (Ti), tantalum, molybdenum (Mo), or any alloys thereof. In some embodiments, different conductive contacts may be formed along a given source/drain trench with dielectric fill 604 between them to electrically isolate them from one another. A top surface of conductive contact 902 may be polished to be substantially coplanar with a top surface of gate electrode 804 (or any dielectric cap layers on gate electrode 804).

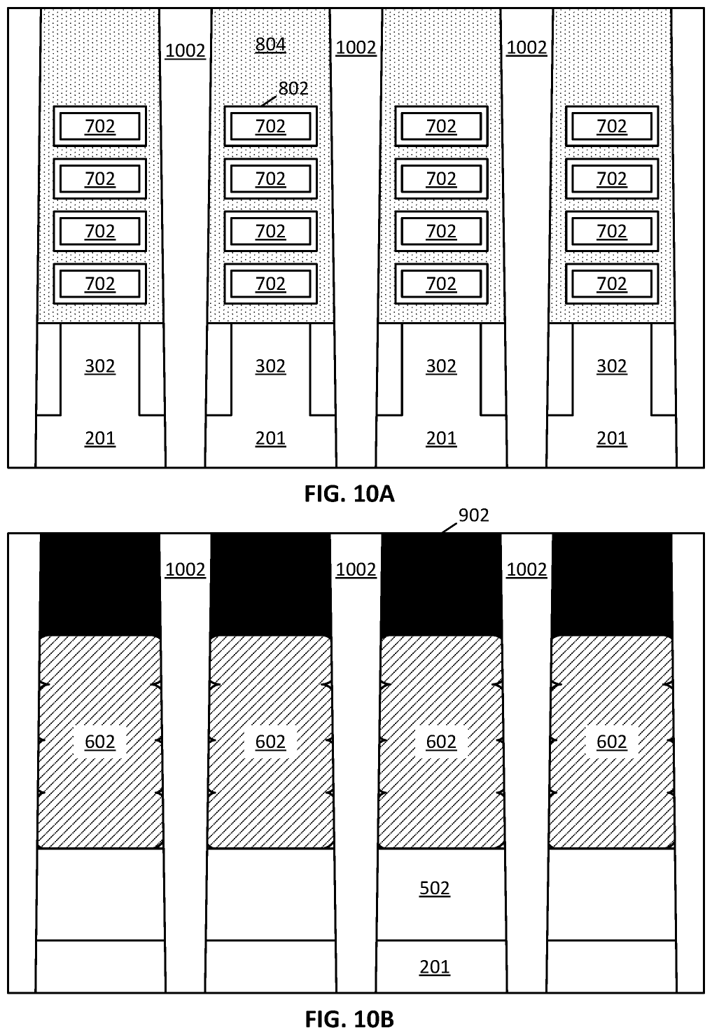

FIGS. 10A and 10B depict the cross-section views of the structure shown in FIGS. 9A and 9B, respectively, following the formation of dielectric walls 1002, according to some embodiments. Dielectric walls 1002 act like gate cuts through the gate structure to form isolated gate electrodes 804 for each semiconductor device. Dielectric walls 1002 further extend along the first direction between adjacent source or drain regions 602 within the source/drain trench. Dielectric walls 1002 may be formed by first forming trench-like high-aspect ratio recesses through a thickness of the gate structure and into at least a portion of substrate 201, according to some embodiments. A metal gate etch process may be used that iteratively etches through portions of gate electrode 804 while simultaneously protecting the sidewalls of the recess from lateral etching to provide a high height-to-width aspect ratio (e.g., aspect ratio of 5:1 or higher, or 10:1 or higher). The recesses extend in the first direction to also cut through a total thickness of conductive contact 902, and a total thickness of sacrificial material 502 within the source/drain trench. Due to the closeness of the devices, the recesses may also expose portions of source or drain regions 602.

According to some embodiments, the recesses are filled with one or more dielectric materials to form dielectric walls 1002. Dielectric walls 1002 may include only silicon dioxide or silicon nitride or silicon carbide. In some examples, dielectric walls 1002 include a first dielectric layer deposited first and a second dielectric layer or dielectric fill formed on the first dielectric layer. The first dielectric layer may include a high-k dielectric material (e.g., materials with a dielectric constant higher than that of silicon oxide or higher than 3.9) while the second dielectric layer may include a low-k dielectric material (e.g. materials with a dielectric constant equal to or lower than that of silicon oxide, such as porous silicon oxide, or equal to or lower than 3.9). Since dielectric walls 1002 are formed after the formation of the gate structure, gate dielectric 802 is also not present along any sidewall of dielectric walls 1002 within the gate trench. Due to the depth of the etched trenches, dielectric walls 1002 extend at least below a full thickness of sacrificial material 502. Dielectric walls 1002 may have a greatest width in the second direction (e.g. along a top surface) between about 5 nm and about 30 nm. The width of dielectric walls 1002 may taper down as the dielectric walls 1002 extend deeper towards substrate 201 due to the fabrication process.

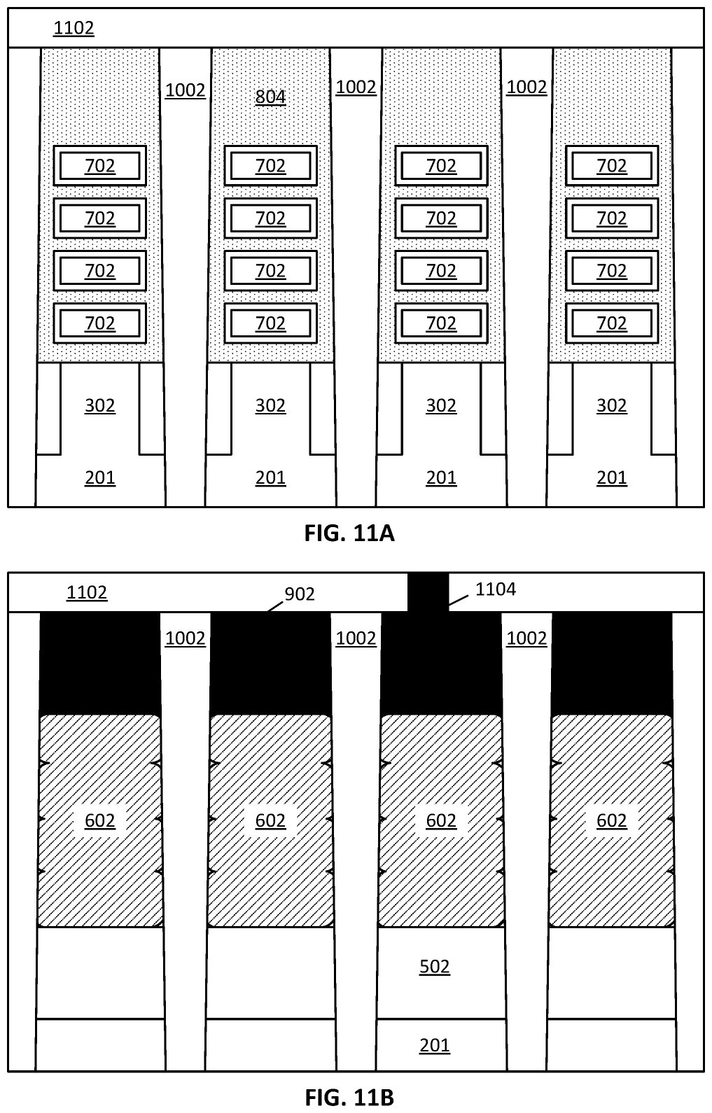

FIGS. 11A and 11B depict the cross-section views of the structure shown in FIGS. 10A and 10B, respectively, following the formation of various BEOL structures such as one or more interconnect layers, according to some embodiments. An example interconnect layer includes a dielectric layer 1102 and one or more conductive vias 1104. Dielectric layer 1102 may include any suitable dielectric material, such as silicon dioxide, silicon nitride, or silicon oxynitride. Conductive via 1104 may include any suitable conductive materials, such as tungsten, ruthenium, molybdenum, or cobalt. In some examples, conductive via 1104 includes the same conductive material as conductive contact 902. Conductive via 1104 may include one or more barrier layers that include tantalum or titanium.

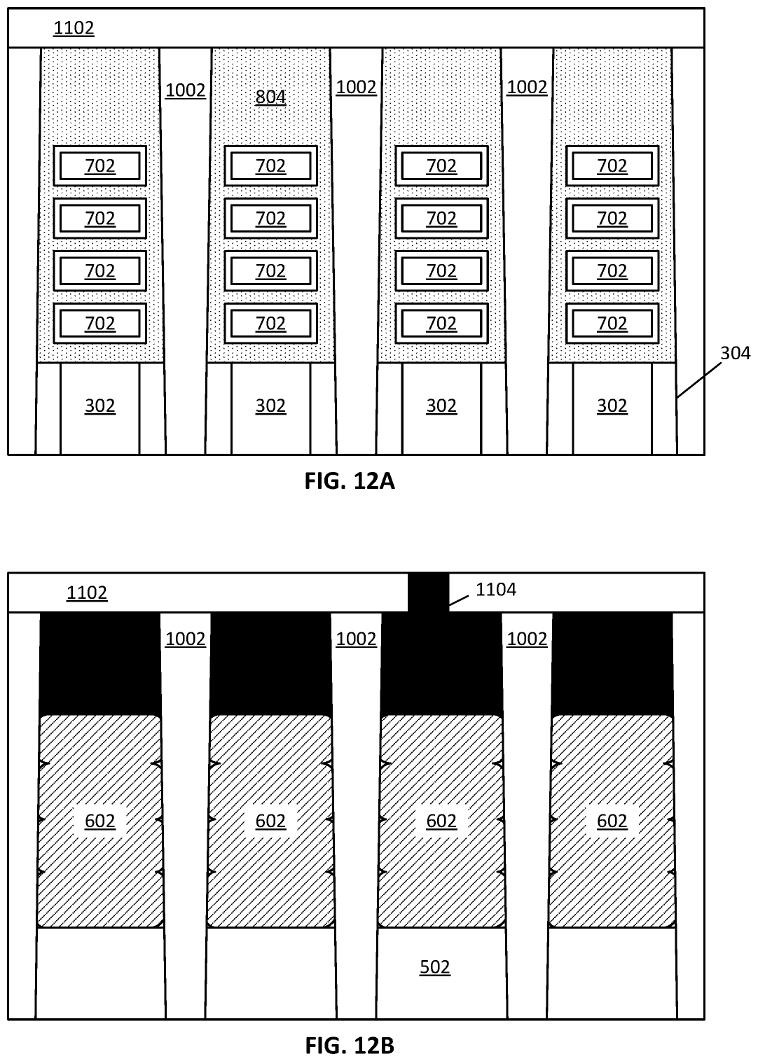

FIGS. 12A and 12B depict the cross-section views of the structure shown in FIGS. 11A and 11B, respectively, following the backside removal of substrate 201, according to some embodiments. Substrate 201 may be polished away via CMP or another grinding process to remove the substrate material. According to some embodiments, substrate 201 continues to be thinned away at least until sacrificial material 502 is exposed from the backside in the source/drain trench. In some examples, portions of subfin regions 302 and/or dielectric fill 304 may also be exposed from the backside in the gate trench. According to some embodiments, bottom surfaces of dielectric walls 1002 are also exposed on the backside of the structure following the removal of substrate 201.

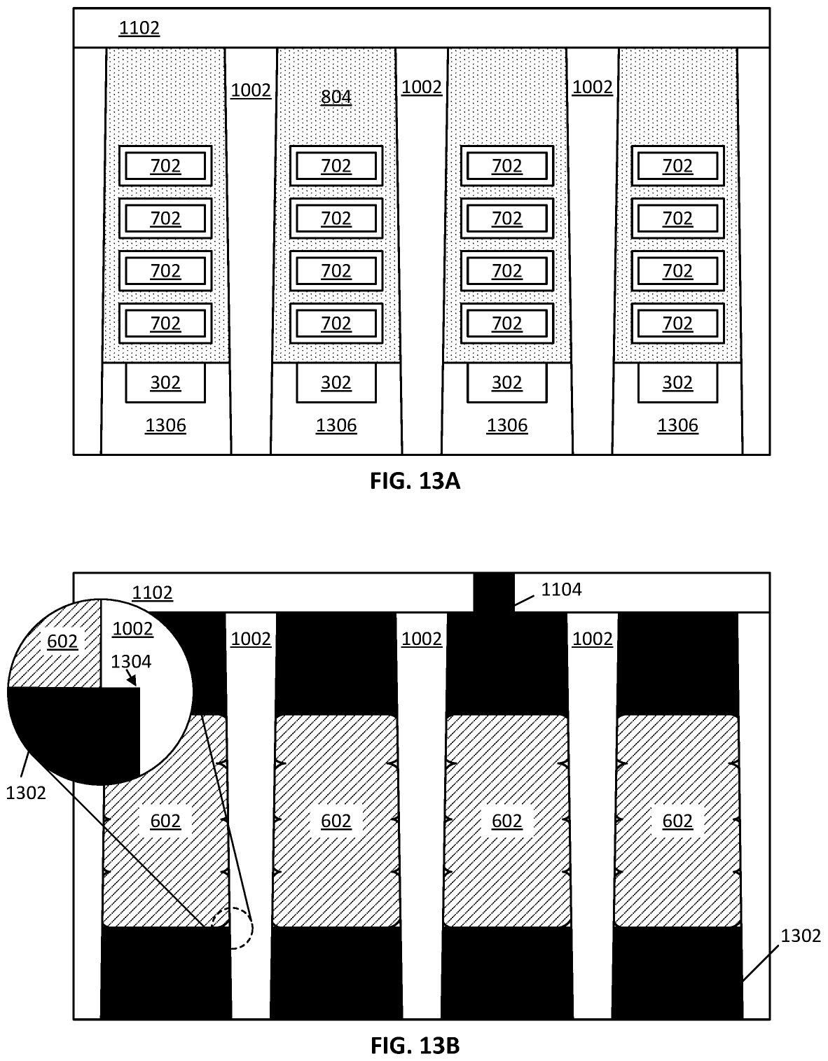

FIGS. 13A and 13B depict the cross-section views of the structure shown in FIGS. 12A and 12B, respectively, following the replacement of sacrificial material 502 with backside contacts 1302, according to some embodiments. Sacrificial material 502 may be selectively removed using any suitable isotropic etching process. Backside contacts 1302 may include any of the same materials discussed above for conductive contact 902, and may be the same conductive material as conductive contact 902. Backside contacts 1302 directly abut an underside of corresponding source or drain regions 602 and are isolated from adjacent contacts by dielectric walls 1002. As such, dielectric walls 1002 extend between each adjacent pair of backside contacts 1302 and extend along an entire thickness of backside contacts 1302, according to some embodiments. The bottom surface of backside contacts 1302 may be polished to be substantially coplanar with the bottom surface of dielectric walls 1002.

According to some embodiments, the isotropic removal of sacrificial material 502 may cause some degree of lateral etching to occur in the portion of dielectric walls 1002 adjacent to sacrificial material 502. As a result, backside contacts 1302 may extend partially into dielectric walls 1002, forming a shoulder feature 1304 as shown in the expanded view. For example, backside contacts 1302 may extend up to 1 nm, up to 2 nm, or up to 3 nm into dielectric walls 1002.

According to some embodiments, the exposed ends of subfin regions 302 may be recessed with the recessed volume filled with another dielectric fill 1306. In some examples, dielectric fill 1306 is substantially the same material as dielectric fill 304, such that the two materials form a common dielectric fill around subfin regions 302. In some other embodiments, dielectric fill 304 is removed and replaced by dielectric fill 1306. In any case, the bottom surface of dielectric fill 1306 may be polished to be substantially coplanar with the bottom surface of dielectric walls 1002.

FIGS. 14A and 14B depict the cross-section views of the structure shown in FIGS. 13A and 13B, respectively, following the formation of backside interconnect structures, according to some embodiments. An example backside interconnect layer includes a dielectric layer 1402 and one or more conductive traces 1404a/1404b. Dielectric layer 1402 may include any suitable dielectric material, such as silicon dioxide, silicon nitride, or silicon oxynitride. Conductive traces 1404a/1404b may include any suitable conductive materials, such as tungsten, ruthenium, molybdenum, or cobalt. In some examples, conductive traces 1404a/1404b include the same conductive material as backside contact 1302. In some examples, a first conductive trace 1404a provides a conductive pathway between adjacent backside contacts 1302 while a second conductive trace 1404b provides a conductive pathway between different adjacent backside contacts 1302. Dielectric walls 1002 do not extend between first conductive trace 1404a and second conductive trace 1404b, according to some embodiments.

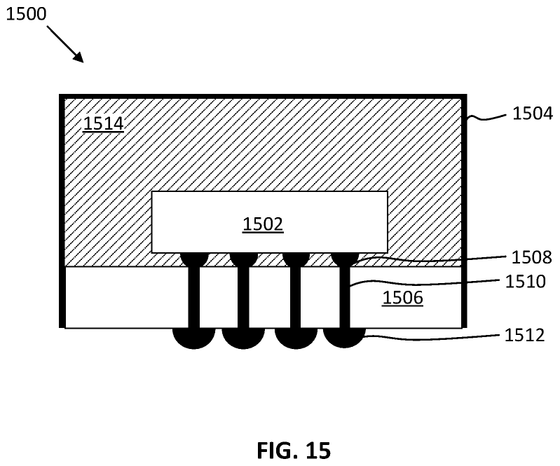

FIG. 15 illustrates an example embodiment of a chip package 1500. As can be seen, chip package 1500 includes one or more dies 1502. One or more dies 1502 may include at least one integrated circuit having semiconductor devices, such as any of the semiconductor devices disclosed herein. One or more dies 1502 may include any other circuitry used to interface with other devices formed on the dies, or other devices connected to chip package 1500, in some example configurations.

As can be further seen, chip package 1500 includes a housing 1504 that is bonded to a package substrate 1506. The housing 1504 may be any standard or proprietary housing, and provides, for example, electromagnetic shielding and environmental protection for the components of chip package 1500. The one or more dies 1502 may be conductively coupled to a package substrate 1506 using connections 1508, which may be implemented with any number of standard or proprietary connection mechanisms, such as solder bumps, ball grid array (BGA), pins, or wire bonds, to name a few examples. Package substrate 1506 may be any standard or proprietary package substrate, but in some cases includes a dielectric material having conductive pathways (e.g., including conductive vias and lines) extending through the dielectric material between the faces of package substrate 1506, or between different locations on each face. In some embodiments, package substrate 1506 may have a thickness less than 1 millimeter (e.g., between 0.1 millimeters and 0.5 millimeters), although any number of package geometries can be used. Additional conductive contacts 1512 may be disposed at an opposite face of package substrate 1506 for conductively contacting, for instance, a printed circuit board (PCB). One or more vias 1510 extend through a thickness of package substrate 1506 to provide conductive pathways between one or more of connections 1508 to one or more of contacts 1512. Vias 1510 are illustrated as single straight columns through package substrate 1506 for ease of illustration, although other configurations can be used (e.g., damascene, dual damascene, through-silicon via). In still other embodiments, vias 1510 are fabricated by multiple smaller stacked vias, or are staggered at different locations across package substrate 1506. In the illustrated embodiment, contacts 1512 are solder balls (e.g., for bump-based connections or a ball grid array arrangement), but any suitable package bonding mechanism may be used (e.g., pins in a pin grid array arrangement or lands in a land grid array arrangement). In some embodiments, a solder resist is disposed between contacts 1512, to inhibit shorting.

In some embodiments, a mold material 1514 may be disposed around the one or more dies 1502 included within housing 1504 (e.g., between dies 1502 and package substrate 1506 as an underfill material, as well as between dies 1502 and housing 1504 as an overfill material). Although the dimensions and qualities of the mold material 1514 can vary from one embodiment to the next, in some embodiments, a thickness of mold material 1514 is less than 1 millimeter. Example materials that may be used for mold material 1514 include epoxy mold materials, as suitable. In some cases, the mold material 1514 is thermally conductive, in addition to being electrically insulating.

### Methodology

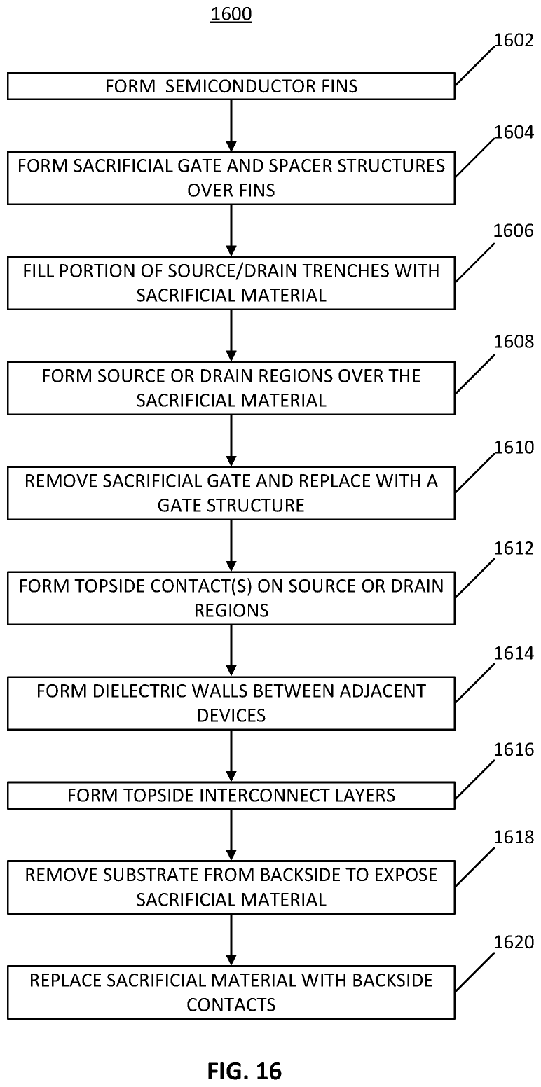

FIG. 16 is a flow chart of a method 1600 for forming at least a portion of an integrated circuit, according to an embodiment. Various operations of method 1600 may be illustrated in FIGS. 2A-14A and 2B-14B. However, the correlation of the various operations of method 1600 to the specific components illustrated in the aforementioned figures is not intended to imply any structural and/or use limitations. Rather, the aforementioned figures provide one example embodiment of method 1600. Other operations may be performed before, during, or after any of the operations of method 1600. Some of the operations of method 1600 may be performed in a different order than the illustrated order.

Method 1600 begins with operation 1602 where a plurality of parallel semiconductor fins are formed, according to some embodiments. The semiconductor material in the fins may be formed from a substrate such that the fins are an integral part of the substrate (e.g., etched from a bulk silicon substrate). Alternatively, the fins can be formed of material deposited onto an underlying substrate. In one such example case, a blanket layer of silicon germanium (SiGe) can be deposited onto a silicon substrate, and then patterned and etched to form a plurality of SiGe fins extending from that substrate. In another such example, the fins include alternating layers of material (e.g., alternating layers of silicon and SiGe) that facilitates forming of nanowires and nanoribbons during a gate forming process where one type of the alternating layers are selectively etched away so as to liberate the other type of alternating layers within the channel region, so that a gate-all-around (GAA) process can then be carried out. The alternating layers can be blanket deposited and then etched into fins, or deposited into fin-shaped trenches. The fins may also include a cap structure over each fin that is used to define the locations of the fins during, for example, an RIE process. The cap structure may be a dielectric material, such as silicon nitride.

According to some embodiments, a dielectric fill is formed around subfin portions of the one or more fins. In some embodiments, the dielectric fill extends between each pair of adjacent parallel fins and runs lengthwise in the same direction as the fins. In some embodiments, the anisotropic etching process that forms the fins also etches into a portion of the substrate and the dielectric fill may be formed within the recessed portions of the substrate. Accordingly, the dielectric fill acts as shallow trench isolation (STI) between adjacent fins. The dielectric fill may be any suitable dielectric material, such as silicon oxide.

Method 1600 continues with operation 1604 where a sacrificial gate and spacer structures are formed over the fins. The sacrificial gate may be patterned using a gate masking layer in a strip that runs orthogonally over the fins (many gate masking layers and corresponding sacrificial gates may be formed parallel to one another (e.g., forming a cross-hatch pattern with the fins)). The gate masking layer may be any suitable hard mask material, such as CHM or silicon nitride. The sacrificial gate may be formed from any suitable material that can be selectively removed at a later time without damaging the semiconductor material of the fins. In one example, the sacrificial gate includes polysilicon. The spacer structures may be deposited and then etched back such that the spacer structures remain mostly only on sidewalls of any exposed structures, such as on sidewalls of the sacrificial gate. According to some embodiments, the spacer structures may be any suitable dielectric material, such as silicon nitride or silicon oxynitride.

Method 1600 continues with operation 1606 where a portion of the source/drain trenches is filled with sacrificial material. Any portions of the fins not protected by the sacrificial gate and spacer structures may be removed using, for example, an anisotropic etching process. According to some embodiments, the subfin portions of the fins and the dielectric fill adjacent to the subfin portions at the bottom of the source/drain trenches are also removed to expose the underlying substrate. A sacrificial material may then be deposited using any suitable deposition technique (CVD, PECVD, etc.) within the source/drain trenches and on the substrate. The sacrificial material may be recessed to a final height within the source/drain trench such that a top surface of the sacrificial material is substantially coplanar with a top surface of the subfin portions and/or dielectric fill within the gate trenches. The sacrificial material may include titanium nitride or tungsten.

Method 1600 continues with operation 1608 where source or drain regions are formed at the ends of the semiconductor regions of each of the fins. Epitaxial growth of the source or drain regions from the exposed ends of the semiconductor layers in the fins. In some example embodiments, the source or drain regions are NMOS source or drain regions (e.g., epitaxial silicon) or PMOS source or drain regions (e.g., epitaxial SiGe). Another dielectric fill may be formed adjacent to the various source or drain regions for additional electrical isolation between adjacent regions. The dielectric fill may also extend over a top surface of the source or drain regions. As described above, internal gate spacers may be formed during the source/drain processing (e.g., after source/drain recess but prior to epi growth of source/drain regions, using a lateral etch process that selectively recesses sacrificial material of the channel region and then filling that recess with internal gate spacer material). The source or drain regions may be formed directly on the sacrificial material within the source/drain trenches.

Method 1600 continues with operation 1610 where the sacrificial gate is removed and replaced with a gate structure. The sacrificial gate may be removed using an isotropic etching process that selectively removes all of the material from the sacrificial gate, thus exposing the various fins between the set of spacer structures. In the example case where GAA transistors are used, any sacrificial layers within the exposed fins between the spacer structures may also be removed to release nanoribbons, nanosheets, or nanowires of semiconductor material.

The gate structure may include both a gate dielectric and a gate electrode. The gate dielectric is first formed over the exposed semiconductor regions between the spacer structures followed by forming the gate electrode within the remainder of the trench between the spacer structures, according to some embodiments. The gate dielectric may include any number of dielectric layers deposited using a CVD process, such as ALD. The gate electrode can include any number of conductive material layers, such as any metals, metal alloys, or polysilicon. The gate electrode may be deposited using electroplating, electroless plating, CVD, ALD, PECVD, or PVD, to name a few examples.

Method 1600 continues with operation 1612 where one or more topside contacts are formed on at least the upper surface of one or more of the source or drain regions. A top portion of the dielectric fill within the source/drain trench may first be recessed until at least a top surface of the source or drain regions are exposed. Then, the one or more topside contacts may be formed within the recessed volume above the source or drain regions. The topside contacts may include any suitably conductive material such as tungsten, ruthenium (Ru), cobalt (Co), titanium (Ti), tantalum, molybdenum (Mo), or any alloys thereof. In some embodiments, different topside contacts may be formed along a given source/drain trench with dielectric fill between them to electrically isolate them from one another. A top surface of the topside contacts may be polished to be substantially coplanar with a top surface of the gate electrode or a top surface of the spacer structures along the sides of the gate structure.

Method 1600 continues with operation 1614 where dielectric walls are formed between adjacent pairs of devices. Deep recesses are first formed through at least a full thickness of the gate structure and extending into the source/drain trenches between source or drain regions where the recesses extend at least through a full thickness of the sacrificial material. The deep recesses may be formed using a metal gate etch process that iteratively etches through portions of the gate electrode while simultaneously protecting the sidewalls of the recess from lateral etching to provide a high height-to-width aspect ratio (e.g., aspect ratio of 5:1 or higher, or 10:1 or higher). According to some embodiments, the recesses also cut through portions of the topside contacts and/or portions of the source or drain regions.

The deep recesses are filled with one or more dielectric materials to form the dielectric walls. For example, the dielectric material may include only silicon dioxide or silicon nitride. In some examples, the dielectric material includes a first dielectric layer and a second dielectric layer on the first dielectric layer within a remaining volume of the deep recesses. The first dielectric layer may include a high-k dielectric material (e.g. materials with a dielectric constant higher than that of silicon oxide or higher than 3.9) while the second dielectric layer may include a low-k dielectric material (e.g. materials with a dielectric constant equal to or lower than that of silicon oxide or equal to or lower than 3.9).

Method 1600 continues with operation 1616 where one or more topside interconnect layers are formed. Each interconnect layer may include a dielectric layer and one or more conductive vias or traces to make contact to lower and/or upper layers or to lower device structures.

Method 1600 continues with operation 1618 where the substrate is removed from the backside to expose the underside of the sacrificial material. According to some embodiments, the substrate is polished away via CMP or another grinding process to remove the substrate material. The substrate may be thinned at least until the bottom surface of sacrificial material is exposed from the backside in the source/drain trench. In some examples, portions of the subfin regions and/or the dielectric fill in the gate trench may also be exposed from the backside in the gate trench. According to some embodiments, bottom surfaces of the dielectric walls are also exposed on the backside of the structure following the removal of the substrate, since the dielectric walls extend through an entire thickness of the sacrificial material.

Method 1600 continues with operation 1620 where the sacrificial material is removed and replaced with backside contacts. The sacrificial material may be selectively removed using any suitable isotropic etching process. The backside contacts may include any of the same materials discussed above for the topside contacts, and may be the same conductive material as the topside contacts. The backside contacts directly abut an underside of corresponding source or drain regions and are isolated from adjacent backside contacts by the dielectric walls. As such, the dielectric walls extend between each adjacent pair of backside contacts and extend along an entire thickness of the backside contacts, according to some embodiments. The bottom surface of the backside contacts may be polished to be substantially coplanar with the bottom surface of the dielectric walls.

### Example System

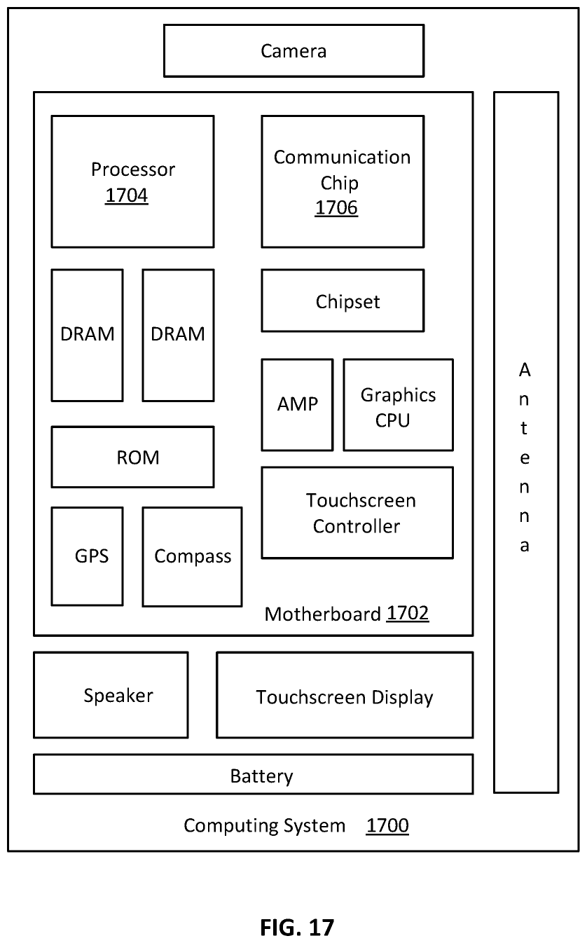

FIG. 17 is an example computing system implemented with one or more of the integrated circuit structures as disclosed herein, in accordance with some embodiments of the present disclosure. As can be seen, the computing system 1700 houses a motherboard 1702. The motherboard 1702 may include a number of components, including, but not limited to, a processor 1704 and at least one communication chip 1706, each of which can be physically and electrically coupled to the motherboard 1702, or otherwise integrated therein. As will be appreciated, the motherboard 1702 may be, for example, any printed circuit board (PCB), whether a main board, a daughterboard mounted on a main board, or the only board of system 1700, etc.

Depending on its applications, computing system 1700 may include one or more other components that may or may not be physically and electrically coupled to the motherboard 1702. These other components may include, but are not limited to, volatile memory (e.g., DRAM), non-volatile memory (e.g., ROM), a graphics processor, a digital signal processor, a crypto processor, a chipset, an antenna, a display, a touchscreen display, a touchscreen controller, a battery, an audio codec, a video codec, a power amplifier, a global positioning system (GPS) device, a compass, an accelerometer, a gyroscope, a speaker, a camera, and a mass storage device (such as hard disk drive, compact disk (CD), digital versatile disk (DVD), and so forth). Any of the components included in computing system 1700 may include one or more integrated circuit structures or devices configured in accordance with an example embodiment (e.g., a module including an integrated circuit device on a substrate, the substrate having one or more semiconductor devices with backside conductive contacts isolated by dielectric walls, as variously provided herein). In some embodiments, multiple functions can be integrated into one or more chips (e.g., for instance, note that the communication chip 1706 can be part of or otherwise integrated into the processor 1704).

The communication chip 1706 enables wireless communications for the transfer of data to and from the computing system 1700. The term “wireless” and its derivatives may be used to describe circuits, devices, systems, methods, techniques, communications channels, etc., that may communicate data through the use of modulated electromagnetic radiation through a non-solid medium. The term does not imply that the associated devices do not contain any wires, although in some embodiments they might not. The communication chip 1706 may implement any of a number of wireless standards or protocols, including, but not limited to, Wi-Fi (IEEE 802.11 family), WiMAX (IEEE 802.16 family), IEEE 802.20, long term evolution (LTE), Ev-DO, HSPA+, HSDPA+, HSUPA+, EDGE, GSM, GPRS, CDMA, TDMA, DECT, Bluetooth, derivatives thereof, as well as any other wireless protocols that are designated as 3G, 4G, 5G, and beyond. The computing system 1700 may include a plurality of communication chips 1706. For instance, a first communication chip 1706 may be dedicated to shorter range wireless communications such as Wi-Fi and Bluetooth and a second communication chip 1706 may be dedicated to longer range wireless communications such as GPS, EDGE, GPRS, CDMA, WiMAX, LTE, Ev-DO, and others.

The processor 1704 of the computing system 1700 includes an integrated circuit die packaged within the processor 1704. In some embodiments, the integrated circuit die of the processor includes onboard circuitry that is implemented with one or more semiconductor devices as variously described herein. The term “processor” may refer to any device or portion of a device that processes, for instance, electronic data from registers and/or memory to transform that electronic data into other electronic data that may be stored in registers and/or memory.

The communication chip 1706 also may include an integrated circuit die packaged within the communication chip 1706. In accordance with some such example embodiments, the integrated circuit die of the communication chip includes one or more semiconductor devices as variously described herein. As will be appreciated in light of this disclosure, note that multi-standard wireless capability may be integrated directly into the processor 1704 (e.g., where functionality of any chips 1706 is integrated into processor 1704, rather than having separate communication chips). Further note that processor 1704 may be a chip set having such wireless capability. In short, any number of processor 1704 and/or communication chips 1706 can be used. Likewise, any one chip or chip set can have multiple functions integrated therein.

In various implementations, the computing system 1700 may be a laptop, a netbook, a notebook, a smartphone, a tablet, a personal digital assistant (PDA), an ultra-mobile PC, a mobile phone, a desktop computer, a server, a printer, a scanner, a monitor, a set-top box, an entertainment control unit, a digital camera, a portable music player, a digital video recorder, or any other electronic device that processes data or employs one or more integrated circuit structures or devices formed using the disclosed techniques, as variously described herein.

It will be appreciated that in some embodiments, the various components of the computing system 1700 may be combined or integrated in a system-on-a-chip (SoC) architecture. In some embodiments, the components may be hardware components, firmware components, software components or any suitable combination of hardware, firmware or software.

### FURTHER EXAMPLE EMBODIMENTS

The following examples pertain to further embodiments, from which numerous permutations and configurations will be apparent.
Example 1 is an integrated circuit that includes a first semiconductor device having a first semiconductor region extending in a first direction from a first source or drain region, and a first gate electrode extending in a second direction over the first semiconductor region, and a second semiconductor device having a second semiconductor region extending in the first direction from a second source or drain region, and a second gate electrode extending in the second direction over the second semiconductor region. The second source or drain region is adjacent to the first source or drain region along the second direction. The integrated circuit further includes a first conductive contact on an underside of the first source or drain region, a second conductive contact on an underside of the second source or drain region, and a dielectric wall extending in the first direction between and contacting both the first gate electrode and the second gate electrode, between the first source or drain region and the second source or drain region, and between the first conductive contact and the second conductive contact.
Example 2 includes the integrated circuit of Example 1, wherein the dielectric wall directly separates the first conductive contact from the second conductive contact.
Example 3 includes the integrated circuit of Example 1 or 2, further comprising a first conductive layer on the first conductive contact and a second conductive layer on the second conductive contact, wherein the dielectric wall does not extend between the first conductive layer and the second conductive layer.
Example 4 includes the integrated circuit of Example 3, further comprising a dielectric layer between the first conductive layer and the second conductive layer.
Example 5 includes the integrated circuit of Example 4, wherein the dielectric layer comprises silicon and oxygen.
Example 6 includes the integrated circuit of any one of Examples 1-5, further comprising a third conductive contact on a topside of the first source or drain region and a fourth conductive contact on a topside of the second source or drain region, wherein the dielectric wall extends in the first direction directly between the third conductive contact and the fourth conductive contact.
Example 7 includes the integrated circuit of any one of Examples 1-6, wherein the dielectric wall comprises silicon and nitrogen.
Example 8 includes the integrated circuit of any one of Examples 1-7, wherein the dielectric wall has a greatest width in the second direction between about 5 nm and about 30 nm.
Example 9 includes the integrated circuit of any one of Examples 1-8, wherein the first semiconductor region comprises a plurality of first semiconductor nanoribbons and the second semiconductor region comprises a plurality of second semiconductor nanoribbons.
Example 10 includes the integrated circuit of Example 9, wherein the plurality of first semiconductor nanoribbons and the plurality of second semiconductor nanoribbons comprise germanium, silicon, or a combination thereof.
Example 11 includes the integrated circuit of any one of Examples 1-10, wherein the second direction is substantially perpendicular to the first direction.
Example 12 includes the integrated circuit of any one of Examples 1-11, wherein a portion of the first conductive contact and/or the second conductive contact extends into the dielectric wall.
Example 13 is a printed circuit board comprising the integrated circuit of any one of Examples 1-12.
Example 14 is an electronic device that includes a chip package comprising one or more dies. At least one of the one or more dies includes a first semiconductor region extending in a first direction from a first source or drain region, and a first gate electrode extending in a second direction over the first semiconductor region, and a second semiconductor device having a second semiconductor region extending in the first direction from a second source or drain region, and a second gate electrode extending in the second direction over the second semiconductor region. The second source or drain region is adjacent to the first source or drain region along the second direction. The at least one of the one or more dies further includes a first conductive contact on an underside of the first source or drain region, a second conductive contact on an underside of the second source or drain region, and a dielectric wall extending in the first direction between and contacting both the first gate electrode and the second gate electrode, between the first source or drain region and the second source or drain region, and between the first conductive contact and the second conductive contact.
Example 15 includes the electronic device of Example 14, wherein the dielectric wall directly separates the first conductive contact from the second conductive contact.
Example 16 includes the electronic device of Example 14 or 15, wherein the at least one of the one or more dies further comprises a first conductive layer on the first conductive contact and a second conductive layer on the second conductive contact, wherein the dielectric wall does not extend between the first conductive layer and the second conductive layer.
Example 17 includes the electronic device of Example 16, wherein the at least one of the one or more dies further comprises a dielectric layer between the first conductive layer and the second conductive layer.
Example 18 includes the electronic device of Example 17, wherein the dielectric layer comprises silicon and oxygen.
Example 19 includes the electronic device of any one of Examples 14-18, wherein the at least one of the one or more dies further comprises a third conductive contact on a topside of the first source or drain region and a fourth conductive contact on a topside of the second source or drain region, wherein the dielectric wall extends in the first direction directly between the third conductive contact and the fourth conductive contact.
Example 20 includes the electronic device of any one of Examples 14-19, wherein the dielectric wall comprises silicon and nitrogen.
Example 21 includes the electronic device of any one of Examples 14-20, wherein the dielectric wall has a width in the second direction between about 5 nm and about 30 nm.
Example 22 includes the electronic device of any one of Examples 14-21, wherein the first semiconductor region comprises a plurality of first semiconductor nanoribbons and the second semiconductor region comprises a plurality of second semiconductor nanoribbons.
Example 23 includes the electronic device of Example 22, wherein the plurality of first semiconductor nanoribbons and the plurality of second semiconductor nanoribbons comprise germanium, silicon, or a combination thereof.
Example 24 includes the electronic device of any one of Examples 14-23, wherein the second direction is substantially perpendicular to the first direction.
Example 25 includes the electronic device of any one of Examples 14-24, further comprising a printed circuit board, wherein the chip package is coupled to the printed circuit board.
Example 26 is a method of forming an integrated circuit. The method includes forming a first fin comprising first semiconductor material and an adjacent second fin comprising second semiconductor material, the first and second fins extending above a substrate and extending in a first direction; forming a dielectric layer adjacent to a bottom portion of the first fin and the second fin; forming a sacrificial gate structures and spacer structures extending in a second direction over the first fin and second fin, such that portions of the first fin and second fin are not covered by the sacrificial gate structures and spacer structures; forming a recess between adjacent spacer structures by removing the portions of the first fin and the second fin, the bottom portion of the first fin and the second fin, and an entire thickness of the dielectric layer; forming a sacrificial material within the recess between the adjacent spacer structures; forming a first source or drain region at an end of the first fin within the recess and over the sacrificial material, and forming a second source or drain region at an end of the second fin within the recess and over the sacrificial material. forming a first conductive contact on a top surface of the first source or drain region within the recess and a second conductive contact on a top surface of the second source or drain region within the recess; replacing the sacrificial gate with a gate structure; forming a dielectric wall through an entire thickness of the gate structure and through an entire thickness of the sacrificial material, the dielectric wall extending in the first direction between the first source or drain region and the second source or drain region; removing the substrate to expose a backside of the sacrificial material; removing the sacrificial material; and forming a third conductive contact on a bottom surface of the first source or drain region and forming a fourth conductive contact on a bottom surface of the second source or drain region.
Example 27 includes the method of Example 26, wherein the first semiconductor material includes an alternating stack of first semiconductor layers and second semiconductor layers, the method further comprising removing the second semiconductor layers to form first suspended nanoribbons from the first semiconductor layers.
Example 28 includes the method of Example 26 or 27, wherein the dielectric wall extends in the first direction between the third conductive contact and the fourth conductive contact.
Example 29 includes the method of any one of Examples 26-28, further comprising forming a first conductive layer on the third conductive contact and a fourth conductive layer on the fourth conductive contact.
Example 30 is an integrated circuit that includes a first semiconductor device having a first semiconductor region extending in a first direction from a first source or drain region, and a first gate structure extending in a second direction over the first semiconductor region. The first gate structure includes a first gate electrode and a first gate dielectric. The integrated circuit also includes a second semiconductor device having a second semiconductor region extending in the first direction from a second source or drain region, and a second gate structure extending in the second direction over the second semiconductor region. The second gate structure includes a second gate electrode and a second gate dielectric, and the second source or drain region is adjacent to the first source or drain region along the second direction. The integrated circuit also includes a dielectric layer beneath the first gate structure and the second gate structure, a first conductive contact extending through an entire thickness of the dielectric layer and contacting an underside of the first source or drain region, a second conductive contact extending through the entire thickness of the dielectric layer and contacting an underside of the second source or drain region, and a dielectric wall extending in the first direction between and contacting both the first gate electrode and the second gate electrode, and between the first conductive contact and the second conductive contact. The dielectric wall also extends through an entire thickness of the dielectric layer.
Example 31 includes the integrated circuit of Example 30, wherein the dielectric wall directly separates the first conductive contact from the second conductive contact.
Example 32 includes the integrated circuit of Example 30 or 31, further comprising a first conductive layer on the first conductive contact and a second conductive layer on the second conductive contact, wherein the dielectric wall does not extend between the first conductive layer and the second conductive layer.
Example 33 includes the integrated circuit of Example 32, further comprising a dielectric fill between the first conductive layer and the second conductive layer.
Example 34 includes the integrated circuit of Example 33, wherein the dielectric fill comprises silicon and oxygen.
Example 35 includes the integrated circuit of any one of Examples 30-34, further comprising a third conductive contact on a topside of the first source or drain region and a fourth conductive contact on a topside of the second source or drain region, wherein the dielectric wall extends in the first direction directly between the third conductive contact and the fourth conductive contact.
Example 36 includes the integrated circuit of any one of Examples 30-35, wherein the dielectric wall comprises silicon and nitrogen.
Example 37 includes the integrated circuit of any one of Examples 30-36, wherein the dielectric wall has a width in the second direction between about 5 nm and about 30 nm.
Example 38 includes the integrated circuit of any one of Examples 30-37, wherein the first semiconductor region comprises a plurality of first semiconductor nanoribbons and the second semiconductor region comprises a plurality of second semiconductor nanoribbons.
Example 39 includes the integrated circuit of Example 38, wherein the plurality of first semiconductor nanoribbons and the plurality of second semiconductor nanoribbons comprise germanium, silicon, or a combination thereof.
Example 40 includes the integrated circuit of any one of Examples 30-39, wherein the second direction is substantially perpendicular to the first direction.
Example 41 is a printed circuit board comprising the integrated circuit of any one of Examples 30-40.

The foregoing description of the embodiments of the disclosure has been presented for the purposes of illustration and description. It is not intended to be exhaustive or to limit the disclosure to the precise forms disclosed. Many modifications and variations are possible in light of this disclosure. It is intended that the scope of the disclosure be limited not by this detailed description, but rather by the claims appended hereto.

What is claimed is:

1. An integrated circuit comprising:
a first semiconductor device having a first semiconductor region extending in a first direction from a first source or drain region, and a first gate electrode extending in a second direction over the first semiconductor region;
a second semiconductor device having a second semiconductor region extending in the first direction from a second source or drain region, and a second gate electrode extending in the second direction over the second semiconductor region, the second source or drain region being adjacent to the first source or drain region along the second direction;
a first conductive contact on an underside of the first source or drain region and a second conductive contact on an underside of the second source or drain region; and
a dielectric wall extending in the first direction between and contacting both the first gate electrode and the second gate electrode, the dielectric wall extending in the first direction between the first source or drain region and the second source or drain region, and the dielectric wall extending in the first direction between the first conductive contact and the second conductive contact.

2. The integrated circuit of claim 1, wherein the dielectric wall directly separates the first conductive contact from the second conductive contact.

3. The integrated circuit of claim 1, further comprising a first conductive layer on the first conductive contact and a second conductive layer on the second conductive contact, wherein the dielectric wall does not extend between the first conductive layer and the second conductive layer.

4. The integrated circuit of claim 1, further comprising a third conductive contact on a topside of the first source or drain region and a fourth conductive contact on a topside of the second source or drain region, wherein the dielectric wall extends in the first direction directly between the third conductive contact and the fourth conductive contact.

5. The integrated circuit of claim 1, wherein the first semiconductor region comprises a plurality of first semiconductor nanoribbons and the second semiconductor region comprises a plurality of second semiconductor nanoribbons.

6. The integrated circuit of claim 1, wherein the second direction is substantially perpendicular to the first direction.

7. The integrated circuit of claim 1, wherein a portion of the first conductive contact and/or the second conductive contact extends into the dielectric wall.

8. An electronic device, comprising:
a chip package comprising one or more dies, at least one of the one or more dies comprising
a first semiconductor device having a first semiconductor region extending in a first direction from a first source or drain region, and a first gate electrode extending in a second direction over the first semiconductor region;
a second semiconductor device having a second semiconductor region extending in the first direction from a second source or drain region, and a second gate electrode extending in the second direction over the second semiconductor region, the second source or drain region being adjacent to the first source or drain region along the second direction;
a first conductive contact on an underside of the first source or drain region and a second conductive contact on an underside of the second source or drain region; and
a dielectric wall extending in the first direction between and contacting both the first gate electrode and the second gate electrode, the dielectric wall extending in the first direction between the first source or drain region and the second source or drain region, and the dielectric wall extending in the first direction between the first conductive contact and the second conductive contact.

9. The electronic device of claim 8, wherein the dielectric wall directly separates the first conductive contact from the second conductive contact.

10. The electronic device of claim 8, wherein the at least one of the one or more dies further comprises a first conductive layer on the first conductive contact and a second conductive layer on the second conductive contact, wherein the dielectric wall does not extend between the first conductive layer and the second conductive layer.

11. The electronic device of claim 10, wherein the at least one of the one or more dies further comprises a dielectric layer between the first conductive layer and the second conductive layer.

12. The electronic device of claim 8, wherein the at least one of the one or more dies further comprises a third conductive contact on a topside of the first source or drain region and a fourth conductive contact on a topside of the second source or drain region, wherein the dielectric wall extends in the first direction directly between the third conductive contact and the fourth conductive contact.

13. The electronic device of claim 8, wherein the second direction is substantially perpendicular to the first direction.

14. An integrated circuit comprising:
a first semiconductor device having a first semiconductor region extending in a first direction from a first source or drain region, and a first gate structure extending in a second direction over the first semiconductor region, the first gate structure comprising a first gate electrode and a first gate dielectric;
a second semiconductor device having a second semiconductor region extending in the first direction from a second source or drain region, and a second gate structure extending in the second direction over the second semiconductor region, the second gate structure comprising a second gate electrode and a second gate dielectric, and the second source or drain region being adjacent to the first source or drain region along the second direction;
a dielectric layer beneath the first gate structure and the second gate structure;
a first conductive contact extending through an entire thickness of the dielectric layer and contacting an underside of the first source or drain region, and a second conductive contact extending through the entire thickness of the dielectric layer and contacting an underside of the second source or drain region; and
a dielectric wall extending in the first direction between and contacting both the first gate electrode and the second gate electrode, the dielectric wall extending in the first direction between the first conductive contact and the second conductive contact, and the dielectric wall extending through an entire thickness of the dielectric layer.

15. The integrated circuit of claim 14, wherein the dielectric wall directly separates the first conductive contact from the second conductive contact.

16. The integrated circuit of claim 14, further comprising a first conductive layer on the first conductive contact and a second conductive layer on the second conductive contact, wherein the dielectric wall does not extend between the first conductive layer and the second conductive layer.

17. The integrated circuit of claim 16, further comprising a dielectric fill between the first conductive layer and the second conductive layer.

18. The integrated circuit of claim 14, further comprising a third conductive contact on a topside of the first source or drain region and a fourth conductive contact on a topside of the second source or drain region, wherein the dielectric wall extends in the first direction directly between the third conductive contact and the fourth conductive contact.

19. The integrated circuit of claim 14, wherein the dielectric wall comprises silicon and nitrogen.

20. The integrated circuit of claim 14, wherein the dielectric wall has a width in the second direction between about 5 nm and about 30 nm.
